(19) United States
(12) Patent Application Publication
(10) Pub. No.: US 2020/0295053 A1
(43) Pub. Date: Sep. 17, 2020

(54) THIN-FILM TRANSISTOR SUBSTRATE AND METHOD FOR MANUFACTURING SAME

(71) Applicant: Mitsubishi Electric Corporation, Chiyoda-ku (JP)

(72) Inventors: Hiroya YAMARIN, Tokyo (JP); Takeo FURUHATA, Tokyo (JP); Kazunori INOUE, Kumamoto (JP)

(73) Assignee: Mitsubishi Electric Corporation, Chiyoda-ku (JP)

(21) Appl. No.: 16/487,328

(22) PCT Filed: Nov. 6, 2017
(86) PCT No.: PCT/JP2017/039893

§ 371 Date: Aug. 20, 2019

(30) Foreign Application Priority Data
Apr. 12, 2017 (JP) 2017-078815

(51) Int. Cl. H01L 27/12; H01L 23/552

(52) U.S. Cl. CPC H01L 27/1225; H01L 23/552

(57) ABSTRACT

The disclosure relates to a (thin-film transistor) TFT substrate that includes a light shielding film provided continuously adjacent to a common electrode in a region overlapping with a drain electrode in plan view below a drain electrode. Furthermore, the TFT substrate includes a light shielding film provided below the source electrode in a region where the source electrode and the common electrode overlap in plan view. In addition, in a gate terminal portion, the TFT substrate includes a light shielding film having conductivity above a gate electrode. The light shielding film is electrically connected to the gate electrode, and overlaps with the gate electrode in plan view.

### TECHNICAL FIELD

The present invention relates to a thin-film transistor substrate forming a liquid crystal display apparatus, and a method for manufacturing the same.

### BACKGROUND ART

A thin-film transistor active matrix substrate (hereinafter referred to as “TFT active matrix substrate” or simply abbreviated to “TFT substrate”) using a thin-film transistor (hereinafter also abbreviated to “TFT”) as a switching element is used for an electro-optical apparatus such as, for example, a liquid crystal display apparatus, which is a display apparatus using liquid crystal, or a light emitting display apparatus, which is a display apparatus using a light emitting diode (LED). A semiconductor apparatus having the TFT has characteristics of low power consumption and thinness, and is actively applied to flat panel displays.

Electro-optical elements for a liquid crystal display (hereinafter also referred to as “LCD”) include a simple matrix LCD and a TFT-LCD using a TFT as a switching element. Among them, the TFT-LCD is superior to the simple matrix LCD in terms of display quality, and is widely used in display products such as mobile computers, notebook computers, or televisions.

In general, a TFT-LCD has a liquid crystal display panel having a configuration in which a liquid crystal layer is sandwiched between a TFT active matrix substrate provided with a plurality of TFTs disposed in an array and a counter substrate provided with a color filter and the like. Each of front and back sides of the liquid crystal display panel is provided with a polarizer, and a backlight is further provided on one side thereof. This structure provides a good color display.

Driving methods of liquid crystal in a liquid crystal display apparatus include vertical electric field systems such as a twisted nematic (TN) mode and a vertical alignment (VA) mode, and lateral electric field systems such as an in plane switching (IPS, registered trademark) mode and a fringe field switching (FFS) mode.

In general, a liquid crystal display apparatus of the lateral electric field system is advantageous for widening a viewing angle as compared with the vertical electric field system, and is becoming mainstream in display products such as personal computers and in-vehicle display apparatuses.

In a liquid crystal display panel of the vertical electric field system represented by the TN mode, a pixel electrode to be applied with a voltage corresponding to an image signal is disposed on the TFT active matrix substrate, while a common electrode fixed to a common potential that is a constant potential is disposed on the counter substrate. Therefore, liquid crystal in a liquid crystal layer is driven by an electric field substantially perpendicular to the surface of the liquid crystal display panel.

Whereas, in a liquid crystal display panel of the lateral electric field system, both a pixel electrode and a common electrode are disposed on a TFT active matrix substrate, and the liquid crystal in the liquid crystal layer is driven by an electric field substantially horizontal to the surface of the liquid crystal display panel. In particular, in the TFT active matrix substrate in the FFS mode, a pixel electrode and a common electrode are disposed to be vertically opposed to each other via an insulating film. While either the pixel electrode or the common electrode may be formed below, the one disposed on the lower side is formed in a flat plate shape, and the one disposed on the upper side (the side closer to the liquid crystal layer) is formed in a lattice shape or a comb-tooth shape having a slit.

Conventionally, for a switching element of a TFT active matrix substrate for a liquid crystal display apparatus, amorphous silicon (a-Si) has been used as a semiconductor film for forming a semiconductor channel layer to be an active layer of the TFT.

In recent years, development of TFTs using an oxide semiconductor for a semiconductor channel layer has been actively conducted. The oxide semiconductor has higher mobility than conventional amorphous silicon, and can realize a high-performance TFT. Therefore, it is advantageous for achieving higher definition and lower power consumption of a panel, and practical use for portable devices such as smartphones and mobile computers, personal computers, and the like is being promoted. For an oxide semiconductor, a zinc oxide (ZnO)-based material and an amorphous InGaZnO-based material in which gallium oxide (Ga₂O₃) and indium oxide (In₂O₃) are added to zinc oxide are mainly used.

Similarly to oxide conductors such as amorphous ITO and amorphous InZnO, which are transparent conductors, these oxide semiconductor materials generally have the advantage of being able to be subjected to etching with a weak acid-based solution such as oxalic acid or carboxylic acid, and being easily subjected to pattern processing. Note that amorphous ITO includes, for example, “indium oxide (In₂O₃)+tin oxide (SnO₂)”, and amorphous InZnO includes, for example, “indium oxide (In₂O₃)+zinc oxide (ZnO)”.

However, such an oxide semiconductor material is also subjected to etching damage by an acid solution used for etching processing of a general metal film that is used for a source electrode or a drain electrode of the TFT, which may deteriorate the characteristics. Further, some types of oxide semiconductor material may be dissolved in these acid solutions. Meanwhile, as a general metal film, for example, Cr, Ti, Mo, Ta, Al, Cu, and alloys thereof are considered.

Therefore, as shown in Patent Document 1, for example, in a case of forming a TFT by directly arranging a source electrode and a drain electrode on a semiconductor channel layer made of an oxide semiconductor, there has been a case where the semiconductor channel layer is damaged by an acid solution used for processing of the source electrode and the drain electrode, and TFT characteristics are deteriorated.

Furthermore, in forming a metal film to be a source electrode and a drain electrode on an oxide semiconductor film to be a semiconductor channel layer, there has been a case where the semiconductor channel layer is damaged by oxidation-reduction reaction at the interface, which may deteriorate characteristics of the TFT.

In order to solve this problem, for example, as shown in Patent Document 2, it is conceivable to apply a TFT structure in which a protective insulating layer is formed on an upper layer of a semiconductor channel layer. In this TFT structure, an oxide semiconductor film forming the semiconductor channel layer can be prevented from being damaged or lost, by etching for processing a metal film into the source electrode and the drain electrode. The TFT of this structure is generally called an etching stopper or an etch stopper (ES) TFT.

Moreover, in using the TFT with an oxide as a semiconductor material for these liquid crystal panels, deterioration of reliability due to light incidence from an LED backlight to a semiconductor layer has become a problem. For example, as shown in Patent Document 3, a structure can be considered in which light leakage is prevented by forming a light shielding layer made of an insulating film on the TFT. Furthermore, as shown in Patent Document 4, there is disclosed a structure in which a light shielding layer is formed immediately below a semiconductor layer of a thin-film transistor to prevent entry of LED light.

### PRIOR ART DOCUMENTS

### Patent Documents

Patent Document 1: Japanese Patent Application Laid-Open No. 2007-281409
Patent Document 2: Japanese Patent Application Laid-Open No. 62-235784 (1987)
Patent Document 3: Japanese Patent Application Laid-Open No. 2003-107525
Patent Document 4: Japanese Patent Application Laid-Open No. 2010-039394

### SUMMARY

### Problem to be Solved by the Invention

In manufacturing of a TFT active matrix substrate provided with an ES TFT, in order to form a protective insulating film made of silicon oxide or silicon nitride on an oxide semiconductor film forming a semiconductor channel layer to form an ES layer, at least one photoengraving process needs to be added in the manufacturing. Therefore, there has been a problem that the production capacity is lowered, and the manufacturing cost is increased.

Furthermore, in a general ES TFT, there has been a problem that deterioration in reliability due to an LED backlight reaching an oxide semiconductor film functioning as a semiconductor channel layer cannot be suppressed. The reason is as follows.

An energy band gap of an InGaZnO-based oxide semiconductor film is about 3.0 eV, and various levels exist within an energy band. These levels are excited by light near a wavelength of 450 nm to generate electron-hole pairs that are carriers, and generation of these carriers causes characteristic variations and characteristic fluctuations of a thin-film transistor. In a liquid crystal display apparatus, a white LED is often used, and its spectrum has a strong peak near a wavelength of 450 nm.

The present invention has been made to solve the above problems, and it is an object of the present invention to provide a thin-film transistor substrate having a structure that suppresses light intensity and a light amount of incident light, such as an LED, that is incident on an oxide semiconductor film forming a semiconductor channel layer, and a method for manufacturing a thin-film transistor substrate for realizing the above thin-film transistor substrate by a relatively simple manufacturing method.

### Means to Solve the Problem

A thin-film transistor substrate according to the present invention is a thin-film transistor substrate in which a plurality of pixel configuration regions are arranged in a matrix form, each of the plurality of pixel configuration regions includes a TFT portion and a pixel portion, each of the plurality of pixel configuration regions includes: a gate electrode selectively provided on a substrate; a gate insulating film provided on the gate electrode; a semiconductor channel layer provided on the gate insulating film; a common electrode selectively provided on the substrate; a protective insulating film covering over the substrate including the gate electrode, the gate insulating film, the semiconductor channel layer, and the common electrode; a drain electrode and a source electrode that are electrically connected to the semiconductor channel layer through a drain contact hole and a source contact hole provided in the protective insulating film, and are provided independently of each other; and a pixel electrode provided extending from on the drain electrode to the pixel portion, the TFT portion is configured by the gate electrode, the gate insulating film, the semiconductor channel layer, the source electrode, the drain electrode, and a part of the pixel electrode, the pixel portion is configured by the common electrode and a main part of the pixel electrode, and a first light shielding film is provided below at least one electrode of the source electrode or the drain electrode, in a region overlapping with the at least one electrode in plan view.

### Effects of the Invention

The thin-film transistor substrate in the present invention exhibits effects of: being able to due to the presence of the first light shielding film, suppress light intensity and a light amount of incident light, such as an LED from a back-surface side of the substrate, reflected by the source electrode or the drain electrode to be incident on the semiconductor channel layer; and being able to shield the incident light itself on the semiconductor channel layer.

Objects, features, aspects, and advantages of the present invention will become more apparent from the following detailed description and the accompanying drawings.

### BRIEF DESCRIPTION OF DRAWINGS

FIG. 1 is a plan view showing a configuration of a TFT substrate that is a thin-film transistor substrate forming a liquid crystal display apparatus as a first embodiment of the present invention.

FIG. 2 is a cross-sectional view showing a cross-sectional structure taken along line A-A in FIG. 1.

FIG. 3 is a cross-sectional view showing a cross-sectional structure taken along line B-B in FIG. 1.

FIG. 4 is a cross-sectional view showing a first method of a patterning process of a gate electrode and a gate insulating film in the first embodiment.

FIG. 5 is a cross-sectional view showing the first method of the patterning process in the first embodiment.

FIG. 6 is a cross-sectional view showing the first method of the patterning process in the first embodiment.

FIG. 7 is a cross-sectional view showing the first method of the patterning process in the first embodiment.

FIG. 8 is a cross-sectional view showing the first method of the patterning process in the first embodiment.

FIG. 9 is an explanatory view showing a configuration of a gray tone mask.

FIG. 10 is a graph showing transmittance of the gray tone mask.

FIG. 11 is an explanatory view showing a configuration of a halftone mask.

FIG. 12 is a cross-sectional view showing a second method of a patterning process of the gate electrode and the gate insulating film in the first embodiment.

FIG. 13 is a cross-sectional view showing the second method of the patterning process in the first embodiment.

FIG. 14 is a cross-sectional view showing the second method of the patterning process in the first embodiment.

FIG. 15 is a cross-sectional view showing the second method of the patterning process in the first embodiment.

FIG. 16 is a cross-sectional view showing a forming process of a light shielding film in the first embodiment.

FIG. 17 is a cross-sectional view showing the forming process of the light shielding film in the first embodiment.

FIG. 18 is a cross-sectional view showing the forming process of the light shielding film in the first embodiment.

FIG. 19 is a cross-sectional view showing the forming process of the light shielding film in the first embodiment.

FIG. 20 is a cross-sectional view showing a final process of the TFT substrate of the first embodiment.

FIG. 21 is a cross-sectional view showing the final process of the TFT substrate of the first embodiment.

FIG. 22 is a cross-sectional view showing the final process of the TFT substrate of the first embodiment.

FIG. 23 is a cross-sectional view showing the final process of the TFT substrate of the first embodiment.

FIG. 24 is a cross-sectional view showing a forming process of a light shielding film in a gate terminal portion of the first embodiment.

FIG. 25 is a cross-sectional view showing the forming process of the light shielding film in the gate terminal portion of the first embodiment.

FIG. 26 is a cross-sectional view showing the forming process of the light shielding film in the gate terminal portion of the first embodiment.

FIG. 27 is a cross-sectional view showing the forming process of the light shielding film in the gate terminal portion of the first embodiment.

FIG. 28 is a cross-sectional view showing a configuration of a gate terminal portion in which a light shielding film is not formed.

FIG. 29 is a cross-sectional view showing a configuration of a modification of the gate terminal portion in the first embodiment.

FIG. 30 is a plan view showing a configuration of a TFT substrate as a second embodiment of the present invention.

FIG. 31 is a cross-sectional view showing a cross-sectional structure taken along line C-C in FIG. 30.

FIG. 32 is a cross-sectional view showing a forming process of a light shielding film in the second embodiment.

FIG. 33 is a cross-sectional view showing the forming process of the light shielding film in the second embodiment.

FIG. 34 is a cross-sectional view showing the forming process of the light shielding film in the second embodiment.

FIG. 35 is a cross-sectional view showing the forming process of the light shielding film in the second embodiment.

FIG. 36 is a cross-sectional view showing the forming process of the light shielding film in the second embodiment.

FIG. 37 is a cross-sectional view showing the forming process of the light shielding film in the second embodiment.

FIG. 38 is a plan view showing a configuration of a TFT substrate as a third embodiment of the present invention.

FIG. 39 is a cross-sectional view showing a cross-sectional structure taken along line D-D in FIG. 38.

FIG. 40 is a plan view showing a configuration of a TFT substrate as a fourth embodiment of the present invention.

FIG. 41 is a cross-sectional view showing a cross-sectional structure taken along line E-E in FIG. 40.

FIG. 42 is a plan view showing a configuration of a modification of a TFT substrate as the fourth embodiment of the present invention.

FIG. 43 is a cross-sectional view showing a cross-sectional structure taken along line F-F in FIG. 42.

FIG. 44 is a cross-sectional view showing a modified manufacturing method of the present embodiment.

### DESCRIPTION OF EMBODIMENTS

### First Embodiment

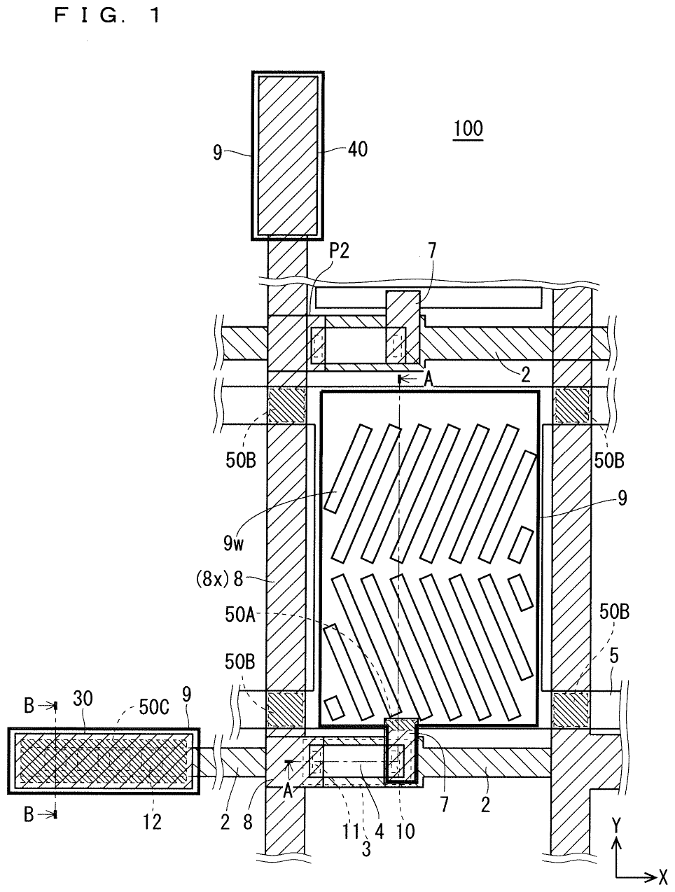

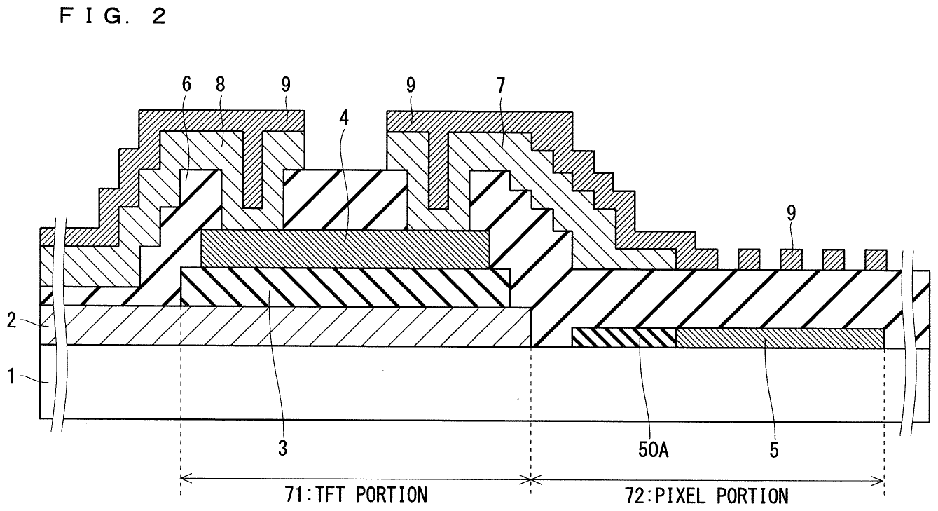

FIG. 1 is a plan view showing a configuration of a TFT substrate 100 that is a thin-film transistor substrate forming a liquid crystal display apparatus as a first embodiment of the present invention, and FIG. 2 is a cross-sectional view showing a cross-sectional structure taken along line A-A in FIG. 1. FIG. 2 shows a cross-sectional structure of a source electrode 8, a TFT portion 71, and a pixel portion 72. Meanwhile, FIG. 1 shows an XY orthogonal coordinate system.

First, with reference to FIGS. 1 and 2, a configuration of the TFT substrate 100 according to the first embodiment, more specifically, the TFT substrate 100 for fringe field switching (FFS) LCD will be described. Although the present invention relates to a TFT substrate, the present invention is characterized in particular by a configuration of a pixel, so that the configuration of the pixel will be mainly described in the following.

FIG. 3 is a cross-sectional view showing a cross-sectional structure taken along line B-B in FIG. 1, and shows a cross-sectional structure of a gate terminal portion 30. Note that the following description will be made on the premise that the TFT substrate 100 is used for a transmissive FFS liquid crystal display apparatus.

As shown in FIG. 1, in the TFT substrate 100, a plurality of gate electrodes 2 extending in the X direction and a plurality of source electrodes 8 extending in the Y direction are disposed to orthogonally intersect with each other, and a TFT is disposed in the vicinity of the intersection of both wires. Moreover, the gate electrode 2 functions as a scanning signal line, and is formed extending to the gate terminal portion 30 disposed outside a pixel configuration portion including the TFT portion 71 and the pixel portion 72. Whereas, the source electrode 8 functions as a display signal line, and is electrically connected to a source terminal portion 40 disposed outside the pixel configuration portion via a source electrode extension region 8x.

The source electrode 8 of the TFT is electrically connected to a semiconductor channel layer 4 through a source contact hole 11, and a drain electrode 7 of the TFT through a drain contact hole 10. The semiconductor channel layer 4 is formed with an oxide semiconductor as a constituent material. Then, a region of the semiconductor channel layer 4 from the drain electrode 7 to the source electrode 8 is to be a channel region of the TFT.

In FIG. 1, a region surrounded by adjacent gate wirings 2 and adjacent source electrodes 8 is to be a pixel configuration region of one unit. Note that the pixel configuration region includes the gate electrode 2 and the source electrode 8. Then, a first electrode is formed in the pixel portion 72 provided adjacent to the TFT portion 71, which is a formation region of the TFT in the pixel configuration region.

Then, a second electrode for liquid crystal control is provided in a structure having a slit above the first electrode so as to substantially face the entire surface. In the configuration in which a common voltage is applied to the first electrode and a display voltage is applied to the second electrode, the second electrode is referred to as a pixel electrode 9, and the first electrode is referred to as a common electrode 5. Hereinafter, in the present specification, the first electrode is described as the common electrode 5, and the second electrode is described as the pixel electrode 9. Meanwhile, as shown in FIG. 1, the pixel electrode 9 is a slit electrode having a plurality of comb-shaped openings 9w.

The TFT substrate 100 is configured as a thin-film transistor substrate in which a plurality of pixel configuration regions are arranged in a matrix form, and each of the plurality of pixel configuration regions has the TFT portion 71 and the pixel portion 72.

The TFT substrate 100 includes the gate electrode 2 selectively provided on a transparent insulating substrate 1, a gate insulating film 3 provided on the gate electrode 2, the semiconductor channel layer 4 provided on the gate insulating film 3, and the common electrode 5 selectively provided on the transparent insulating substrate 1.

Further, the TFT substrate 100 includes: a protective insulating film 6 covering the entire surface on the transparent insulating substrate 1 including the gate electrode 2, the gate insulating film 3, the semiconductor channel layer 4, and the semiconductor channel layer 4; and the drain electrode 7 and the source electrode 8 that are electrically connected to the semiconductor channel layer 4 through the drain contact hole 10 and the source contact hole 11 selectively provided in the protective insulating film 6, and are provided independently of each other.

Then, the TFT substrate 100 further includes the pixel electrode 9 that is adapted to be provided extending from on the drain electrode 7 to the pixel portion 72, the TFT portion 71 is configured by the gate electrode 2, the gate insulating film 3, the semiconductor channel layer 4, the source electrode 7, the drain electrode 8, and a part of the pixel electrode 9, and the pixel portion 72 is configured by the common electrode 5 and a main part of the pixel electrode 9. Note that the main part of the pixel electrode 9 means a rectangular region in plan view having a plurality of openings 9w formed in a region between adjacent gate electrodes 2 and source electrodes 8.

Thus, in each of the plurality of pixel configuration regions, there are provided the gate electrode 2, the gate insulating film 3, the semiconductor channel layer 4, the common electrode 5, the protective insulating film 6, the drain electrode 7, the source electrode 8, and the pixel electrode 9, and there are provided the TFT portion 71 and the pixel portion 72.

As described above, the gate electrode 2 is formed extending to the gate terminal portion 30 outside the pixel configuration region, and the source electrode 8 is formed extending to the source terminal portion 40 outside the pixel configuration region.

Then, as shown in FIGS. 1 and 2, the TFT substrate 100 of the first embodiment has a first feature of having a light shielding film 50A, which is one of first light shielding films continuously provided adjacent to the common electrode 5, below the drain electrode 8 in a region overlapping with the drain electrode 7 in plan view.

Furthermore, as shown in FIG. 1, the TFT substrate 100 of the first embodiment has a second feature of having a light shielding film 50B, which is another one of the first light shielding films provided in a region where the source electrode 8 and the common electrode 5 overlap in plan view, below the source electrode 8.

As described above, in the TFT substrate 100 of the first embodiment, below at least one electrode of the source electrode 8 or the drain electrode 7, the light shielding film 50A and the light shielding film 50B are formed as a first light shielding film provided in a region overlapping in plan view with the at least one electrode. Then, the light shielding film 50A becomes a drain light shielding film, and the light shielding film 50B becomes a source light shielding film.

In addition, as shown in FIG. 3, the TFT substrate 100 of the first embodiment has a third feature of being provided with a light shielding film 50C, which is a second light shielding film having conductivity above the gate electrode 2, in the gate terminal portion 30. This light shielding film 50C is electrically connected to the gate electrode 2 and overlaps with the gate electrode 2 in plan view.

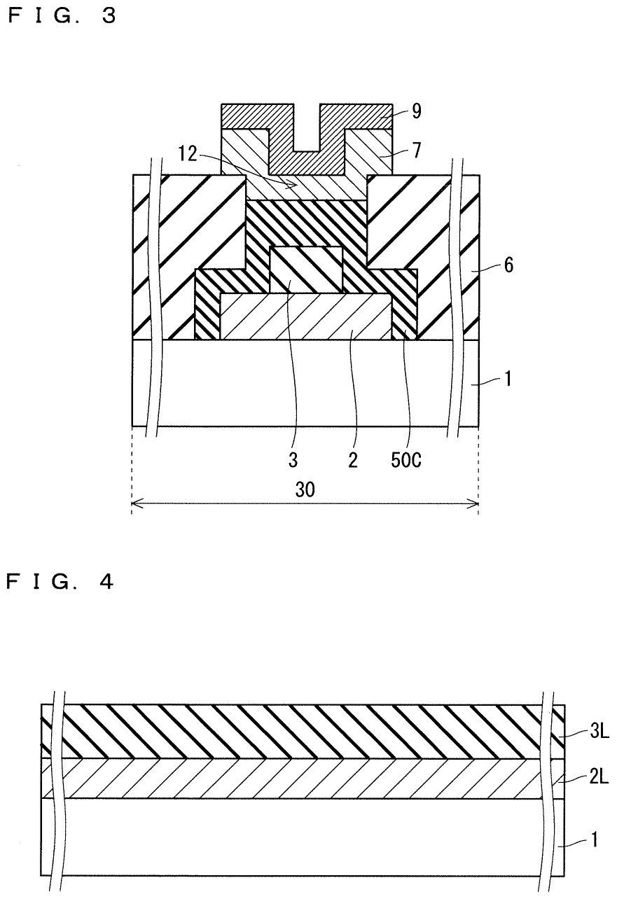

FIGS. 4 to 8 are cross-sectional views showing a first method of a patterning process of the gate electrode 2 and the gate insulating film 3, which is a part of a method for manufacturing the TFT substrate 100 of the first embodiment. Hereinafter, a part of the method for manufacturing the TFT substrate 100 will be described with reference to these drawings.

First, as shown in FIG. 4, the transparent insulating substrate 1 such as glass is prepared.

Then, a conductive layer 2L is formed on the entire surface of the transparent insulating substrate 1 by a sputtering method using an aluminum (Al)-based alloy film, for example, an Al—Ni—Nd film. In the example shown in FIG. 4, an Al—Ni—Nd film having a thickness of 100 nm has been formed to form the conductive layer 2L. Note that Ar gas, Kr gas, or the like can be used as a sputtering gas.

In the first embodiment, the Al—Ni—Nd alloy is used for the conductive layer 2L, but other materials may be used as long as a wiring resistance can be equal to or lower than that of the Al—Ni—Nd alloy. Since the Al—Ni—Nd alloy is mainly composed of Al, the Al—Ni—Nd alloy has high conductivity, and is a material that can also be electrically connected to a transparent conductive film such as ITO, by the added Ni.

Next, an insulating layer 3L is formed on the entire surface of the conductive layer 2L. For example, a silicon oxide film (SiO) is formed to a thickness of 50 nm to 400 nm as the insulating layer 3L by a chemical vapor deposition (CVD) method.

In the first embodiment, since a barrier property to impurity elements adversely affecting TFT characteristics, such as moisture (H₂O), hydrogen (H₂), sodium (Na), or potassium (K), that is, a blocking property is weak, for example, a silicon nitride film (SiN) having an excellent barrier property is further provided under a lower layer of SiO, and the insulating layer 3L is formed in a laminated structure of a silicon oxide film and a silicon nitride film. Meanwhile, the silicon nitride film is formed to a thickness of, for example, 50 nm to 400 nm by the CVD method.

Next, as shown in FIG. 5, a photoresist 21, which is a gate-related resist, is formed by coating on the insulating layer 3L, and the photoresist 21 is patterned in a first photoengraving process. For the photoresist 21, for example, a photoresist material composed of a novolak-based positive photosensitive resin is applied to the insulating layer 3L to a thickness of about 1.5 μm by using a coating method.

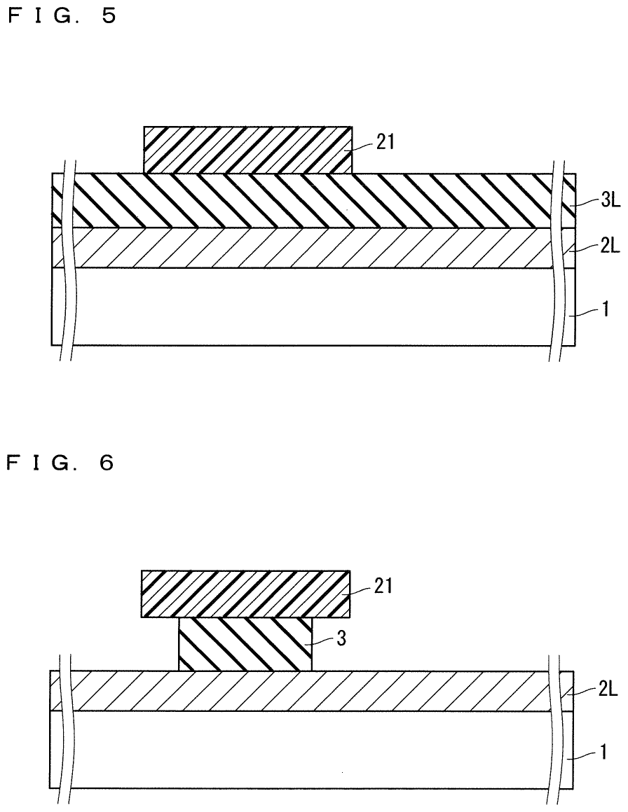

Then, as shown in FIG. 6, by a dry etching method using a fluorine-containing gas such as CHF₃, CF₄, or SF₆ and an oxygen (O₂) gas with the patterned photoresist 21 as an etching mask, an etching process is performed on the insulating layer 3L made of a silicon oxide film and a silicon nitride film. This etching process is a first etching process in the first method above, and at this time, a side etching amount is adjusted to be relatively large by isotropic etching.

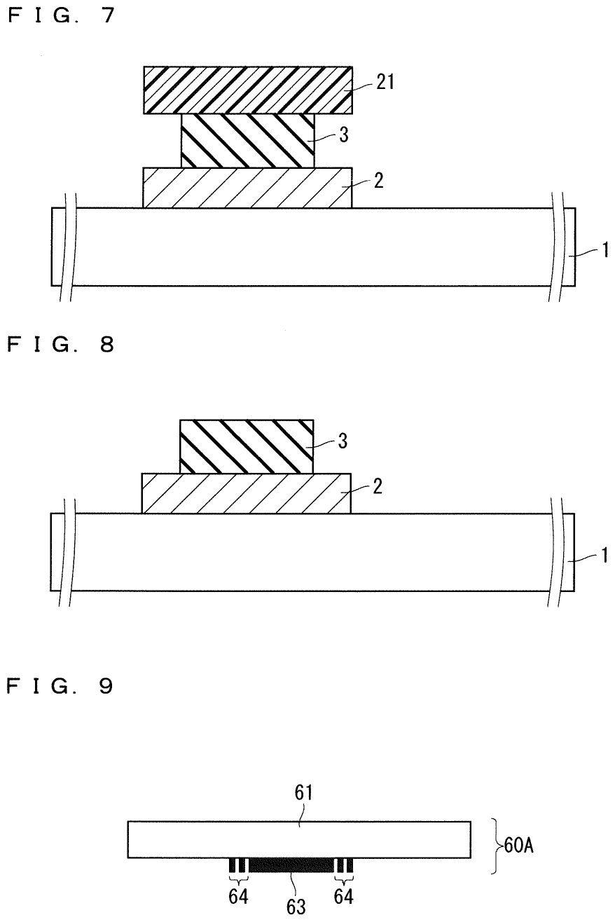

Next, as shown in FIG. 7, the etching process is performed on the conductive layer 2L by wet etching using a PAN solution containing phosphoric acid, acetic acid, and nitric acid, to form the gate electrode 2. This etching process is to be a second etching process in the first method above, and the same photoresist 21 is used as an etching mask. Although the wet etching process is used as the second etching process in the above-described example, the processing may be performed by a dry etching method.

Note that, in the first and second etching processes on the insulating layer 3L and the conductive layer 2L described above, a side etching amount for the insulating layer 3L in the first etching process is adjusted to be larger. As a result, a formation area of the gate insulating film 3 is processed so as to be smaller than a formation area of the gate electrode 2 in plan view, and a gate insulating film reduction structure can be obtained in which the gate insulating film 3 is not formed on a peripheral region of the gate electrode 2.

Next, as shown in FIG. 8, the photoresist 21 is peeled and removed using a resist stripping liquid.

As described above, in the first method in patterning the gate electrode 2 and the gate insulating film 3, the above-described gate insulating film reduction structure is realized by performing the first etching process on the gate insulating film 3 with the photoresist 21, which is a gate-related resist, as an etching mask, and performing the second etching process on the gate electrode 2 using the same photoresist 21 as an etching mask.

As shown in FIG. 1, the gate electrode 2 is a plurality of scanning signal lines extending in the X direction, is disposed to orthogonally intersect with the plurality of source electrodes 8, which are display signal lines extending in the Y direction via the gate insulating film 3 and the protective insulating film 6, and the TFT portion 71 is disposed in the vicinity of the intersection of both wires.

In the scanning signal line portion of the gate electrode 2 orthogonally intersecting with the source electrode 8, which is the display signal line, there is assumed a gate insulating film expansion structure having a structure in which a formation area of the gate insulating film 3 is processed to be larger than a formation area of the gate electrode 2 in plan view, and the gate insulating film 3 is left long in an eaves shape from a wiring end portion of the gate electrode 2. Adopting the gate insulating film expansion structure deteriorates coverage of the protective insulating film 6 to be formed later, resulting in higher possibility of causing an inter-electrode circuit between the gate electrode 2 and the source electrode 8. In order to avoid the above possibility, for example, it is desirable to adjust the gate insulating film 3 to be shorter by 1 μm to 10 μm than a width of the gate electrode 2, and to adopt the above-described gate insulating film reduction structure.

Thus, in the TFT substrate 100 of the first embodiment, since the coverage of the protective insulating film 6 with respect to the gate electrode 2 is improved by adopting the above-described gate insulating film reduction structure, the TFT substrate 100 exhibits an effect of being able to make the inter-electrode short circuit with the source electrode 8 provided above and intersecting in plan view to be less likely to occur.

As a second method of patterning the gate insulating film 3 and the semiconductor channel layer 4, a method of using a multi-tone mask as a photomask used for exposure may be used.

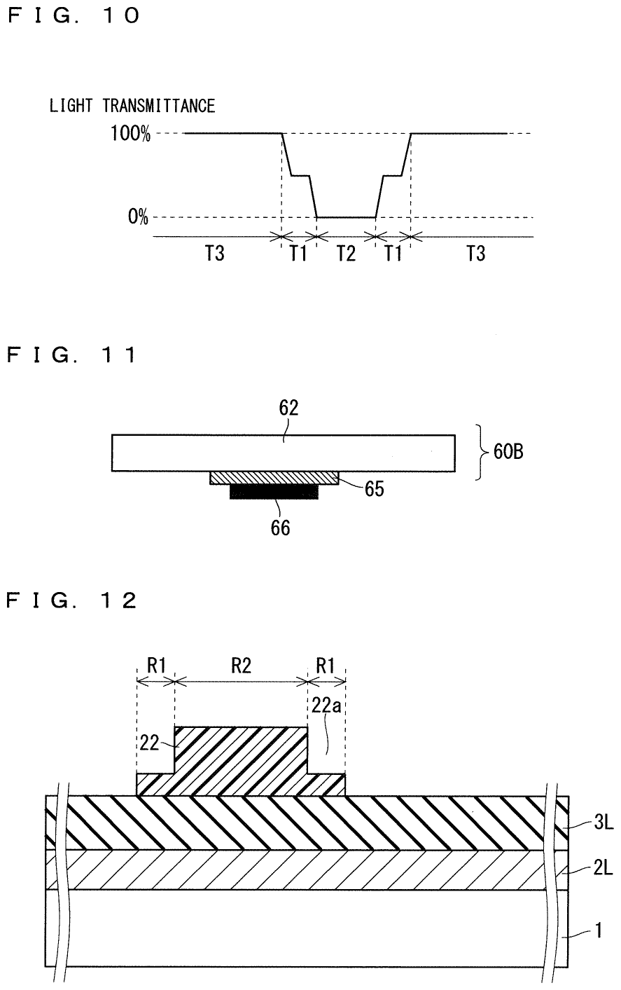

FIG. 9 is an explanatory view showing a configuration of a gray tone mask 60A. FIG. 10 is a graph showing transmittance of the gray tone mask 60A, and FIG. 11 is an explanatory view showing a configuration of a halftone mask 60B.

Hereinafter, a multi-tone mask will be described with reference to FIGS. 9 to 11. The multi-tone mask is a mask capable of performing three exposure levels of: an exposed portion; an intermediate exposed portion; and an unexposed portion, and is an exposure mask in which transmitted light is emitted to a photoresist, which is a photosensitive resin, at a plurality of different intensities.

Using the multi-tone mask makes it possible to form a photoresist in a pattern shape having first and second regions of a plurality of, typically, two different film thicknesses, by one-time exposure and development process. Therefore, the number of exposure masks (photomasks) can be reduced by using the multi-tone mask.

As a representative example of the multi-tone mask, there are the gray tone mask 60A shown in FIG. 9 and the halftone mask 60B shown in FIG. 11.

As shown in FIG. 9, the gray tone mask 60A is configured to include a light projecting substrate 61, a light shielding portion 63 formed on a lower surface of the light projecting substrate 61, and a diffraction grating portion 64 disposed adjacent to the light shielding portion 63. In the light shielding portion 63, the light transmittance is 0%. Whereas, for the diffraction grating portion 64, the light transmittance can be controlled by setting a distance of the light transmitting portion such as a slit, a dot, and a mesh to a distance equal to or less than a resolution limit of light to be used for exposure.

Meanwhile, for the diffraction grating portion 64, either a periodic slit, dot, or mesh, or an aperiodic slit, dot, or mesh can be used. As the light projecting substrate 61, a light transmitting substrate such as quartz or a film can be used. The light shielding portion 63 and the diffraction grating portion 64 can be formed using a light shielding material that absorbs light, such as chromium or chromium oxide.

When the gray tone mask 60A is irradiated with exposure light, as shown in FIG. 10, the light transmittance is 0% in a region T2 where the light shielding portion 63 is formed, while the light transmittance is 100% in a region T3 where the light shielding portion 63 and the diffraction grating portion 64 are not provided.

Further, in a region T1 where the diffraction grating portion 64 is provided, the light transmittance can be adjusted in a range of 10 to 70%. Adjustment of the light transmittance in the diffraction grating portion 64 is possible by adjustment of a spacing and a pitch of the slit, the dot, or the mesh of the diffraction grating.

Further, as shown in FIG. 11, the halftone mask 60B is configured to include a light transmitting substrate 62, a semi-transmissive portion 65 formed on a lower surface of the light transmitting substrate 62, and a light shielding portion 66 formed on a central portion on a lower surface of the semi-transmissive portion 65.

For the semi-transmissive portion 65, MoSiN, MoSi, MoSiO, MoSiON, CrSi, or the like can be used. The light shielding portion 66 can be formed using a light shielding material that absorbs light, such as chromium or chromium oxide. For adjusting the light transmittance, adjustment by the material of the semi-transmissive portion 65 is possible as in FIG. 10. Specifically, the light transmittance is 0% in a region T2 where the light shielding portion 66 is formed, the light transmittance is 100% in a region T3 where the semi-transmissive portion 65 and the light shielding portion 66 both are not provided, and the light transmittance is 10 to 70% in a region T1 where only the semi-transmissive portion 65 is provided.

FIGS. 12 to 15 are cross-sectional views showing a second method of a patterning process of the gate electrode 2 and the gate insulating film 3 using the halftone mask 60B.

As shown in FIG. 12, the conductive layer 2L is formed on the entire surface of the transparent insulating substrate 1, and the insulating layer 3L is formed on the conductive layer 2L. At this time, the insulating layer 3L is formed in a laminated structure of a silicon oxide film and a silicon nitride film.

Thereafter, by applying a photoresist 22 on the insulating layer 3L, and using, for example, the halftone mask 60B shown in FIG. 11 as a multi-tone mask to adjust an exposure amount of the partial exposure amount, that is, a photosensitive amount, and the development conditions, the photoresist 22 is patterned into a structure selectively having a stepped portion 22a with a lower formation height than other regions. The patterned photoresist 22 has a region R1 that is a first region and a region R2 that is a second region, and the region R1 is a region formed around the region R2. In this case, the stepped portion 22a is provided by forming the region R1 to have a film thickness thinner than a film thickness of the region R2.

That is, an exposure region corresponding to the region T1 of the halftone mask 60B is to be the region R1 of the photoresist 22, and an exposure region corresponding to the region T2 is to be the region R2 of the photoresist 22. As described above, the photoresist 22 is patterned in a structure having the stepped portion 22a in a peripheral region thereof by the photoengraving process using the halftone mask 60B.

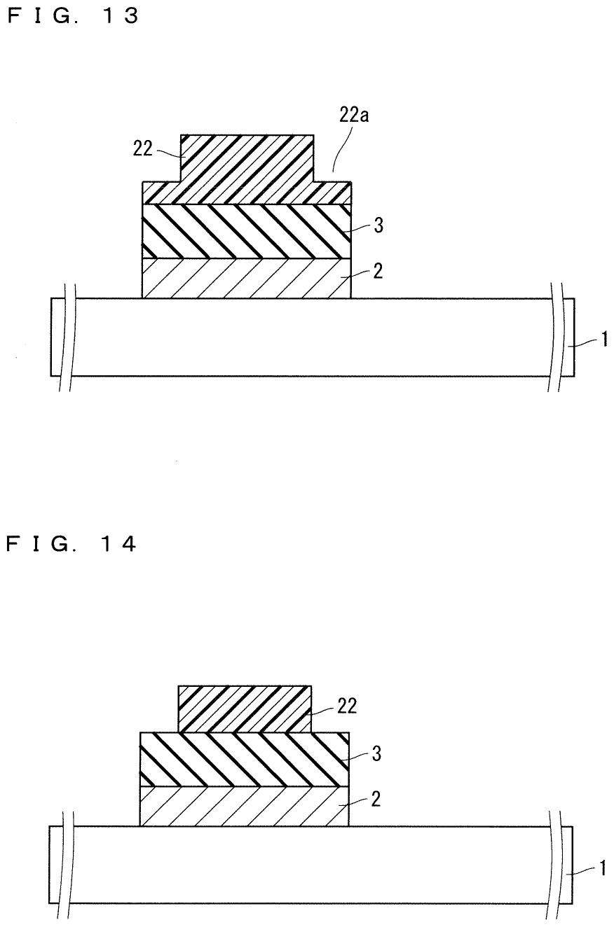

Then, as shown in FIG. 13, by a dry etching method using a fluorine-containing gas such as CHF₃, CF₄, or SF₆ and an oxygen (O₂) gas with the patterned photoresist 22 as an etching mask, an etching process is performed on the insulating layer 3L having a laminated structure of a silicon oxide film and a silicon nitride film.

Next, the etching process is performed on the conductive layer 2L by wet etching using a solution containing phosphoric acid, acetic acid, and nitric acid, to form the gate electrode 2. As described above, the etching process continuously performed on the insulating layer 3L and the conductive layer 2L with the photoresist 22 having the stepped portion 22a as an etching mask is to be the first etching process in the second method.

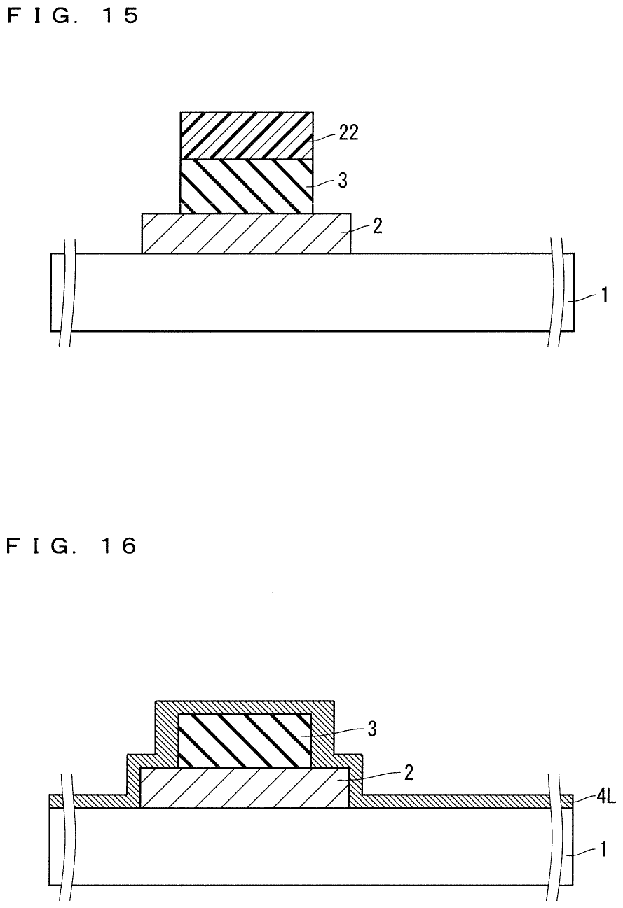

Next, as shown in FIGS. 14 and 15, the stepped portion 22a of the photoresist 22 is removed, and the second etching process is performed on the gate insulating film 3 by a dry etching method using a fluorine-containing gas such as CHF₃, CF₄, or SF₆ and an oxygen (O₂) gas with the photoresist 22 from which the stepped portion 22a is removed as an etching mask, to selectively remove a part of the gate insulating film 3. Thereafter, the photoresist 22 is removed using a resist stripping liquid.

As a result, the gate insulating film 3 is processed so as to be inside the gate electrode 2 by an amount of the region R1 of the stepped portion 22a shown in FIG. 12. As a result, a formation area of the gate insulating film 3 is processed so as to be smaller than a formation area of the gate electrode 2 in plan view, and a gate insulating film reduction structure can be obtained in which the gate insulating film 3 is not formed on a peripheral region of the gate electrode 2.

As described above, in the second method related to patterning of the gate electrode 2 and the gate insulating film 3, the above-described gate insulating film reduction structure is realized by performing the first etching process on the gate electrode 2 and the gate insulating film 3 with the photoresist 22, which is a gate-related resist, as an etching mask as shown in FIG. 13, and performing the second etching process on the gate insulating film 3 using the same photoresist 22 from which the stepped portion 22a is removed as an etching mask.

That is, in the above first and second methods related to patterning of the gate electrode 2 and the gate insulating film 3, the first etching process is performed on at least one of the gate insulating film 3 or the gate electrode 2 with the photoresist 21 or the photoresist 22, which is a gate-related resist, as an etching mask. Then, the above-described gate insulating film reduction structure is realized by performing the second etching process on at least one of the gate insulating film 3 or the gate electrode 2, with the same photoresist 21 or photoresist 22 as an etching mask.

At this time, the first etching target is the gate insulating film 3 in the first method above, and the gate insulating film 3 and the gate electrode 2 in the second method above, while the second etching target is the gate electrode 2 in the first method above, and the gate insulating film 3 in the second method above.

FIGS. 16 to 19 are cross-sectional views showing a forming process of the light shielding film 50A, which is a part of the method for manufacturing the TFT substrate 100 of the first embodiment. This process is performed subsequently to the first method above shown in FIGS. 4 to 8 or the second method above shown in FIGS. 12 to 15.

As shown in FIG. 16, an oxide semiconductor formation layer 4L is formed on the entire surface of the transparent insulating substrate 1 including the gate electrode 2 and the gate insulating film 3. In the present embodiment, an InGaZnO-based oxide semiconductor in which gallium oxide (G₂O₃) and zinc oxide (ZnO) are added to indium oxide (In₂O₃) is used as the oxide semiconductor formation layer 4L.

Here, for example, the oxide semiconductor formation layer 4L is formed by a DC sputtering method using an InGaZnO target [In₂O₃.(G₂O₃).(ZnO)₂] in which an atomic composition ratio of In:Ga:Zn:O is 1:1:1:4. At this time, as a sputtering gas, known argon (Ar) gas, krypton (Kr) gas, or the like can be used. The InGaZnO film formed by using such a sputtering method is to be an oxide film in an oxygen ion deficient state (in the above example, the composition ratio of 0 is less than 4) in which an atomic composition ratio of oxygen is usually smaller than the stoichiometric composition. As described above, the composition ratio to be the content of oxygen may be different selectively as the oxide semiconductor to be the constituent material of the oxide semiconductor formation layer 4L.

Therefore, it is desirable to mix oxygen (O₂) gas with Ar gas for sputtering. Here, sputtering is performed using a mixed gas in which 10% of O₂ gas at a partial pressure ratio is added to Ar gas, to form an InGaZnO-based oxide semiconductor formation layer 4L with a thickness of 40 nm, for example. Note that the InGaZnO film may have an amorphous structure.

Next, as shown in FIG. 17, the photoresist 23 formed by applying on the oxide semiconductor formation layer 4L is patterned by performing a second patterning process by the photoengraving process. For the resist 23, for example, a photoresist material composed of a novolak-based positive photosensitive resin is applied to the oxide semiconductor formation layer 4L, to a thickness of about 1.5 μm by using a coating method.

In the first embodiment, by adjusting an exposure amount of a partial exposure amount and the development conditions by using the halftone mask 60B, patterning is performed into the photoresist 23 that selectively has a stepped portion 23a as shown in FIG. 17, similarly to the photoresist 22 shown in FIGS. 12 to 15.

Then, with the patterned photoresist 23 as an etching mask, by performing wet etching using a solution containing oxalic acid on the oxide semiconductor formation layer 4L, the semiconductor channel layer 4 is formed on the gate insulating film 3, and at the same time, the common electrode 5 is selectively formed on the transparent insulating substrate 1. The solution containing oxalic acid preferably contains oxalic acid in a range of 1 to 10 wt %. In the first embodiment, an aqueous solution containing 5 wt % of oxalic acid is used.

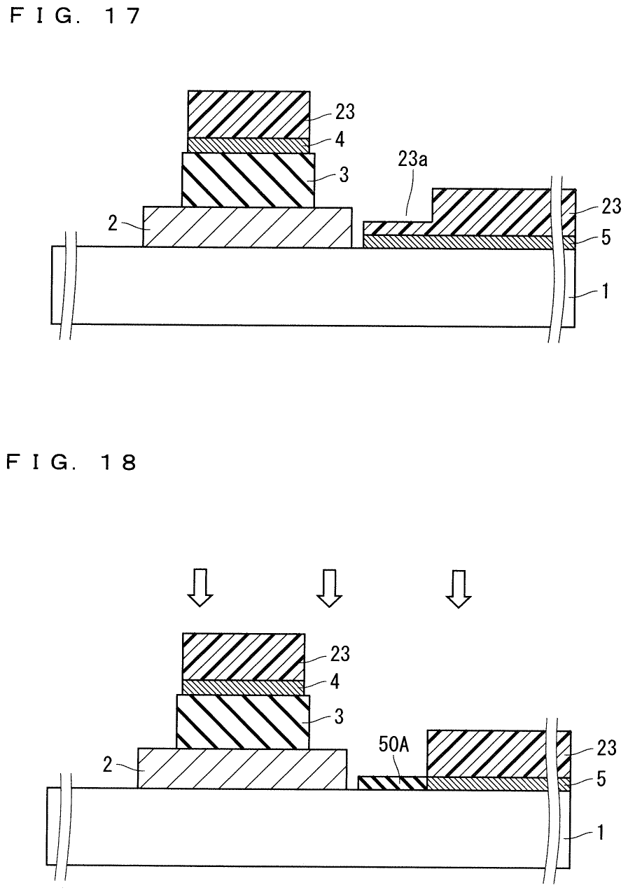

Next, as shown in FIG. 18, the stepped portion 23a of the photoresist 23 is removed by a dry etching method using a fluorine-containing gas such as CHF₃, CF₄, or SF₆ and an oxygen (O₂) gas. Thereafter, with the photoresist 23 from which the stepped portion 23a is removed as a mask, reduction treatment by plasma treatment including hydrogen (H₂), helium (He), and nitrogen (N₂) is performed on a part of the common electrode 5 whose surface is exposed, to form the light shielding film 50A. As a result, the light shielding film 50A is formed continuously adjacent to the common electrode 5. Meanwhile, the reduction treatment and the process of removing the oxide in the common electrode 5 are meant.

Although not shown in FIGS. 16 to 18, by forming, also on a planned formation region of the light shielding film 50B of the common electrode 5 shown in FIG. 1, a stepped portion similar to the stepped portion 23a of the photoresist 23 formed on the planned formation region of the light shielding film 50A shown in FIG. 17, the light shielding film 50B can also be formed at a time of formation of the light shielding film 50A by the reduction treatment.

Thus, since the photoresist 23 having the first and second regions with different film thicknesses is formed by the photoengraving process using the halftone mask 60B, which is a multi-tone mask, the common electrode 5 and the light shielding film 50A and the light shielding film 50B, which are the first light shielding films, can be formed by using one photoresist 23. As a result, the manufacturing process can be simplified by reducing the number of photoengraving processes, to one, required for forming the common electrode 5, the light shielding film 50A, and the light shielding film 50B.

In addition, it is possible to improve resistance loss when current flows through the light shielding film 50A and the light shielding film 50B, by respectively setting specific resistances of the light shielding film 50A and the light shielding film 50B, which are first light shielding films, to be low, by performing plasma treatment as the reduction treatment.

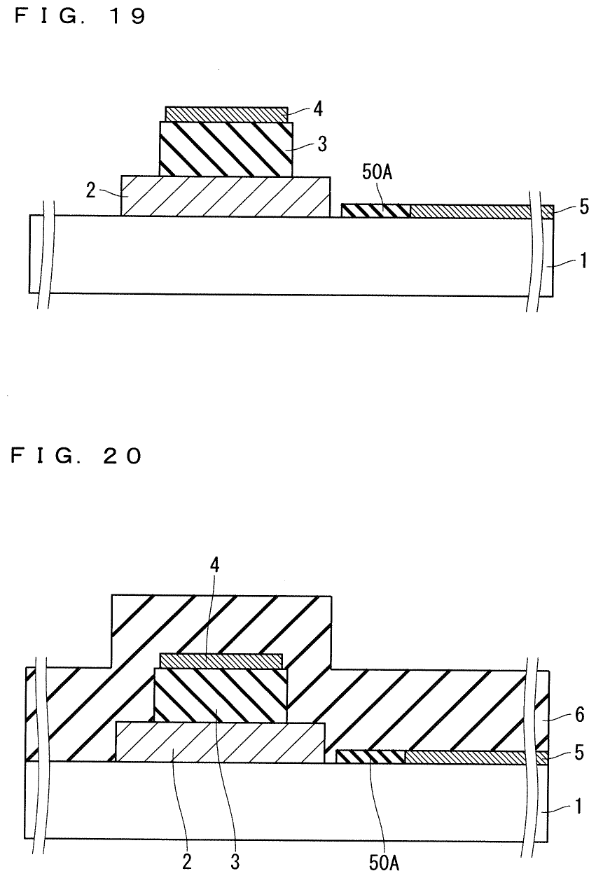

In the first embodiment, hydrogen plasma treatment is performed at 40 W for 120 seconds by using a gas in which helium and hydrogen are mixed in a ratio of 1:1. Thereafter, as shown in FIG. 19, the photoresist 23 is peeled and removed.

Subsequently, the entire transparent insulating substrate 1 including the gate electrode 2, the gate insulating film 3, the semiconductor channel layer 4, the common electrode 5, and the light shielding film 50A is annealed in an air atmosphere at 200 to 400° C. By annealing treatment in a state of containing oxygen, oxygen can be further supplied to the semiconductor channel layer 4 and the common electrode 5 having an oxide semiconductor film as a constituent material, allowing the elimination of the oxygen ion deficiency state to be more reliable. Further, since structural relaxation also simultaneously occurs, structural defects are reduced, and a high-quality semiconductor film is obtained.

While the specific resistances of the semiconductor channel layer 4 and the common electrode 5 are specific resistances of approximately 1×10² Ω·cm or more and 1×10⁵ Ω·cm or less, the light shielding film 50A and the light shielding film 50B subjected to the reduction treatment become about 1×10⁻³ Ω·cm or less, and the nature changes from semiconductor to conductor.

Furthermore, in the light shielding film 50A and the light shielding film 50B subjected to the reduction treatment, a light absorption rate at a wavelength of 500 nm or less increases. It is also well known that a positive hole is injected into the gate insulating film 3, and a threshold voltage of the thin-film transistor changes with time in a case where the gate electrode 2 is negatively applied, since electron-hole pairs and oxygen vacancy levels are excited from defect levels existing near the valence band when light with a wavelength of 450 nm or less is incident on the semiconductor channel layer 4 from LED light, in particular. Therefore, it is important for improving the reliability of the thin-film transistor that, together with the reduction of the defect level, the light is not made incident on the semiconductor channel layer 4 and that the light intensity is weakened even if the light is incident.

Therefore, it is possible to obtain an effect that the light shielding film 50A and the light shielding film 50B subjected to the reduction treatment reduce light intensity of a wavelength that adversely affects the TFT characteristics.

As described above, due to the presence of the light shielding film 50A and the light shielding film 50B, which are the first light shielding films, the TFT substrate 100 according to the first embodiment exhibits the effect of being able to suppress light intensity and a light amount of incident light, such as an LED from a back-surface side of the transparent insulating substrate 1, reflected by the drain electrode 7 or the source electrode 8 to be incident on the semiconductor channel layer 4, and being able to shield the incident light itself to the semiconductor channel layer 4.

As described above, the light shielding film 50A has, as a constituent material, the same oxide semiconductor as the constituent material of the semiconductor channel layer 4, and is provided on the transparent insulating substrate 1 in a state of being electrically separated from the gate electrode 2.

Therefore, in the TFT substrate 100 of the first embodiment, since the light shielding film 50A, which is the first light shielding film, can be formed together with the formation of the semiconductor channel layer 4 after deposition of the oxide semiconductor formation layer 4L, productivity of the thin-film transistor substrate can be improved by reducing the number of masks for patterning.

Further, due to the presence of the light shielding film 50A, which is the drain light shielding film, the TFT substrate 100 can suppress light intensity and a light amount of incident light, such as an LED from a back-surface side of the transparent insulating substrate 1, reflected by the drain electrode 7 to be incident on the semiconductor channel layer 4.

Furthermore, in the TFT substrate 100, since the light shielding film 50A can be formed with a relatively low specific resistance, a wiring resistance associated with the common electrode 5 can be lowered to improve the resistance loss.

In addition, due to the presence of the light shielding film 50B, which is the source light shielding film, the TFT substrate 100 of the first embodiment can suppress light intensity and a light amount of incident light, such as an LED from a back-surface side of the transparent insulating substrate 1, reflected by the source electrode extension region 8x of the source electrode 8 to be incident on the semiconductor channel layer 4.

Furthermore, in the TFT substrate 100, since the light shielding film 50B can be formed with a relatively low specific resistance, a wiring resistance associated with the gate electrode 2 can be lowered to improve the resistance loss.

FIGS. 20 to 23 are cross-sectional views showing a final process, which is a part of the method for manufacturing the TFT substrate 100 of the first embodiment.

First, as shown in FIG. 20, the protective insulating film 6 is formed on the entire surface of the transparent insulating substrate 1 including the gate electrode 2, the gate insulating film 3, the semiconductor channel layer 4, the common electrode 5, and the light shielding film 50A. For example, a silicon oxide film is formed to a thickness of 50 nm to 400 nm as the protective insulating film 6, by using a chemical vapor deposition (CVD) method.

In the first embodiment, since a barrier property to impurity elements adversely affecting TFT characteristics, such as moisture (H₂O), hydrogen (H₂), sodium (Na), or potassium (K), that is, a blocking property is weak, for example, a laminated structure with a silicon oxide film is adopted in which a silicon nitride film or the like excellent in barrier property is provided on an upper layer of SiO. That is, the silicon nitride film is further formed on the silicon oxide film with a thickness of 50 nm to 400 nm by using the CVD method, to obtain the protective insulating film 6.

Meanwhile, as the protective insulating film 6, aluminum oxide (Al₂O₃) or the like may be used, or a laminated structure of the above-described silicon oxide film and silicon nitride film may be used.

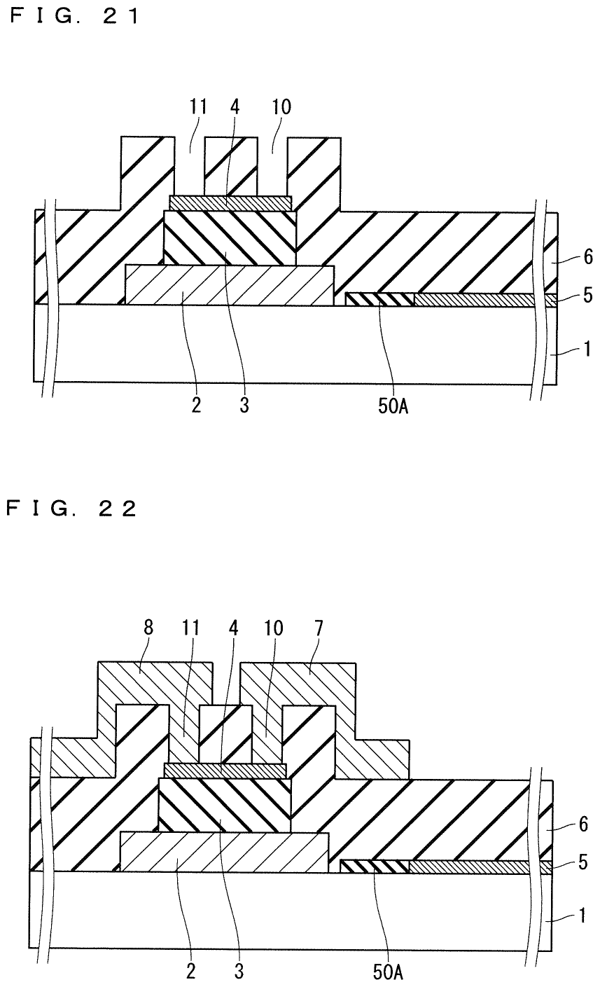

Next, as shown in FIG. 21, the drain contact hole 10 and the source contact hole 11 that selectively penetrate the protective insulating film 6 to reach the surface of the semiconductor channel layer 4 are formed.

Specifically, a photoresist (not shown) is patterned by a third photoengraving process, and then an etching process is performed on the protective insulating film 6 having a laminated structure of a silicon oxide film and a silicon nitride film with the patterned photoresist as an etching mask, by a dry etching method using a fluorine-containing gas such as CHF₃, CF₄, or SF₆ and an oxygen (O₂) gas. As a result, the drain contact hole 10 and the source contact hole 11 can be obtained, and then the photoresist is peeled and removed using a resist stripping liquid.

Next, as a source/drain conductive layer (not shown), a MoNb alloy film and an Al—Ni—Nd alloy film each having a thickness of 100 nm are formed in this order by a DC magnetron sputtering method.

Subsequently, as shown in FIG. 22, the drain electrode 7 and the source electrode 8 are selectively formed by patterning the photoresist (not shown) by a fourth photoengraving process, and performing etching process with the patterned photoresist as a mask, on the source/drain conductive layer by using a wet etching method with a PAN solution, which is a mixed acid containing phosphoric acid, acetic acid, and nitric acid. Thereafter, the photoresist is peeled and removed using a resist stripping liquid.

As a result, the drain electrode 7 electrically connected to the semiconductor channel layer 4 through the drain contact hole 10, and the source electrode 8 electrically connected to the semiconductor channel layer 4 through the source contact hole 11 can be formed independently of each other on the protective insulating film 6.

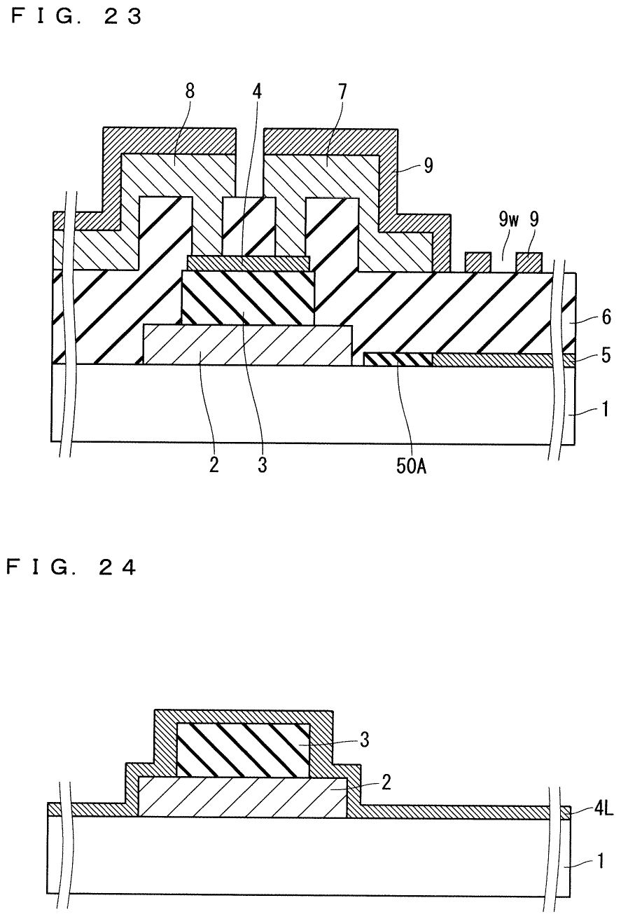

At this time, the drain electrode 7 is formed above the light shielding film 50A as shown in FIG. 23, and is formed so as to overlap with the light shielding film 50A in plan view as shown in FIG. 1.

Note that the semiconductor channel layer 4 dissolves in the PAN solution, but the semiconductor channel layer 4 is not to be removed since the protective insulating film 6 protects the semiconductor channel layer 4 in etching process on the source/drain conductive layer.

Therefore, Ti, Mo, Al, Cu, an alloy of these, a laminated structure, or the like may be used as the drain electrode 7 and the source electrode 8, and processing may be performed using a dry etching method as a processing method.

Subsequently, a conductive layer for a pixel electrode is formed on the entire surface of the transparent insulating substrate 1. The conductive layer for a pixel electrode is, for example, an a-ITO film formed by the DC sputtering method using an ITO target containing indium oxide and tin oxide, and is formed to a thickness of, for example, 100 nm.

Subsequently, as shown in FIG. 23, the pixel electrode 9 is selectively formed by patterning a photoresist (not shown) by a fifth photoengraving process, and performing a wet etching process using a solution containing oxalic acid on the conductive layer for a pixel electrode, with the patterned photoresist as an etching mask. Thereafter, the photoresist is peeled and removed using a resist stripping liquid.

As a result, the pixel electrode 9 is selectively formed on the source electrode 8, on the drain electrode 7, and on the protective insulating film 6, and the structure of the TFT substrate 100 is completed. At this time, the pixel electrode 9 is provided with a slit-shaped opening 9w as shown in FIG. 1. Note that the pixel electrode 9 provided on the source electrode 8 is for protecting the source electrode 8, and does not function as an original pixel electrode.

Thereafter, the entire structure of the TFT substrate 100 is subjected to heat treatment for 60 minutes at a temperature of 230° C. in an air atmosphere, that is, annealing treatment. This annealing treatment allows the amorphous ITO to be completely crystallized and increases the transmittance of the pixel electrode 9, and the TFT substrate 100 shown in FIG. 1 can be finally obtained.

In the first embodiment, the TFT substrate 100 is completed by the five photoengraving processes, but it is also possible to create a TFT substrate having a structure equivalent to that of the TFT substrate 100 shown in FIG. 23 by four photoengraving processes, by patterning a photoresist having first and second regions by using a halftone mask, after reversing the vertical relationship of the drain electrode 7 and the source electrode 8 with the pixel electrode 9, and continuously laminating the conductive layer for a pixel electrode and the drain/source conductive layer.

The method for manufacturing the thin-film transistor substrate according to the first embodiment includes the following steps (a) to (d).

Step (a) is a step of selectively forming a gate electrode (2) on a substrate (1) and forming a gate insulating film (3) on the gate electrode.

Step (b) is a step of forming a semiconductor channel layer (4) on the gate electrode and selectively forming a common electrode (5) on the substrate.

Step (c) is a step of forming a protective insulating film (6) over the entire surface of the substrate including the gate electrode, the gate insulating film, the semiconductor channel layer, and the common electrode.

Step (d) is a step of selectively penetrating the protective insulating film to form a drain contact hole (10) and a source contact hole (11), and forming the source electrode (7) and the drain electrode (8) to be independently of each other and electrically connected to the semiconductor channel layer through the drain contact hole and the source contact hole.

The above step (b) includes the following steps (b-1) to (b-5).

Step (b-1) is a step of forming an oxide semiconductor formation layer (4L) on the entire surface of the substrate including the gate insulating film and the gate electrode.

Step (b-2) is a step of forming, by a photoengraving process using a multi-tone mask, a resist (23) patterned so as to have first and second regions having mutually different film thicknesses on the oxide semiconductor formation layer, in which the first region is formed to have a thinner film thickness than that of the second region.

Step (b-3) is a step of patterning the oxide semiconductor formation layer with the resist having the first and second regions as a mask.

Step (b-4) is a step of patterning such that the first region is removed from the resist and only the second region remains.

Step (b-5) is a step of applying, with the resist having only the second region after the step (b-4) as a mask, reduction treatment on the oxide semiconductor formation layer whose surface is exposed, and forming a first light shielding film, in which a region corresponding to the second region of the oxide semiconductor formation layer is to be the semiconductor channel layer in the TFT portion, and to be the common electrode in the pixel portion.

The reduction treatment performed in the step (b-5) includes plasma treatment using a hydrogen-containing gas.

By setting a specific resistance of the first light shielding film to be low by plasma treatment, it is possible to improve the resistance loss when current flows through the first light shielding film.

Since the resist having the first and second regions having different film thicknesses is formed by the photoengraving process using a multi-tone mask in step (b-2) of step (b), the common electrode and the first light shielding film can be formed with use of one resist in step (b). As a result, the number of photoengraving processes required to form the common electrode and the first light shielding film can be reduced to one, which simplifies the manufacturing process.

Further, the above step (a) includes the following steps (a-1) and (a-2).

Step (a-1) is a step of performing a first etching process on at least one of the gate insulating film or the gate electrode, with a gate-related resist as an etching mask.

Step (a-2) is a step of performing a second etching process on at least one of the gate insulating film or the gate electrode, with the gate-related resist as an etching mask.

After performing step (a), a formation area of the gate insulating film is set smaller than a formation area of the gate electrode in plan view, and the gate insulating film reduction structure is presented in which the gate insulating film is not formed on a peripheral region of the gate electrode.

Since the coverage of the protective insulating film with respect to the gate electrode is improved by obtaining the gate insulating film reduction structure by the first and second etching processes using the same gate-related resist, an inter-electrode short circuit with the source electrode provided on the upper side and intersecting in plan view can be less likely to occur.

Furthermore, the thin-film transistor substrate in which the plurality of pixel configuration regions are arranged in a matrix form of the first embodiment has the following configuration.

The first light shielding film (50A, 50B, 52, 53) has, as a constituent material, a same oxide semiconductor as the constituent material of the semiconductor channel layer, and is provided on the substrate in a state of being electrically separated from the gate electrode.

Therefore, the first light shielding film has, as a constituent material, a same oxide semiconductor as the constituent material of the semiconductor channel layer, and the first light shielding film can be formed together with the formation of the semiconductor channel layer, so that productivity of the thin-film transistor substrate can be improved by reducing the number of masks for patterning.

The first embodiment includes the drain light shielding film (50A), which is formed continuously adjacent to the common electrode and formed in a region overlapping with the drain electrode in plan view.

Due to the presence of the drain light shielding film, it is possible to suppress light intensity and a light amount of incident light, such as an LED from a back-surface side of the substrate, reflected by the drain electrode to be incident on the semiconductor channel layer.

In addition, the source electrode further includes a source electrode extension region (8x) formed toward a source terminal portion (30) disposed outside the pixel configuration region, and the first light shielding film includes a source light shielding film (50B) formed continuously adjacent to the common electrode, in a region where the common electrode and the source electrode extension region overlap in plan view.

In the first embodiment, due to the presence of the source light shielding film, it is possible to suppress light intensity and a light amount of incident light, such as an LED from a back-surface side of the substrate, reflected by the source electrode to be incident on the semiconductor channel layer.

Further, it is characterized in that a formation area of the gate insulating film is set smaller than a formation area of the gate electrode in plan view, and the gate insulating film reduction structure is presented in which the gate insulating film is not formed on a peripheral region of the gate electrode.

Since the coverage of the protective insulating film with respect to the gate electrode is improved by adopting the above-described gate insulating film reduction structure, an inter-electrode short circuit with the source electrode provided on the upper side and intersecting in plan view can be less likely to occur.

The first light shielding film has an oxide semiconductor as a constituent material, and its specific resistance is set to 1×10⁻³ Ω·cm or less, which is lower than a specific resistance of the semiconductor channel layer.

Therefore, by setting a specific resistance of the first light shielding film to be low, it is possible to improve the resistance loss when current flows through the first light shielding film.

FIGS. 24 to 27 are cross-sectional views showing a forming process of the light shielding film 50C in the gate terminal portion 30.

As shown in FIG. 24, the oxide semiconductor formation layer 4L is formed on the entire surface of the transparent insulating substrate 1 including the gate electrode 2 and the gate insulating film 3. This process corresponds to the process shown in FIG. 16. Note that the gate insulating film reduction structure is obtained in which the gate insulating film 3 is not formed on the peripheral region of the gate electrode 2, also in the gate terminal portion 30. That is, the gate insulating film reduction structure is obtained by adopting the first method above shown in FIGS. 4 to 8 or the second method above shown in FIGS. 12 to 15.

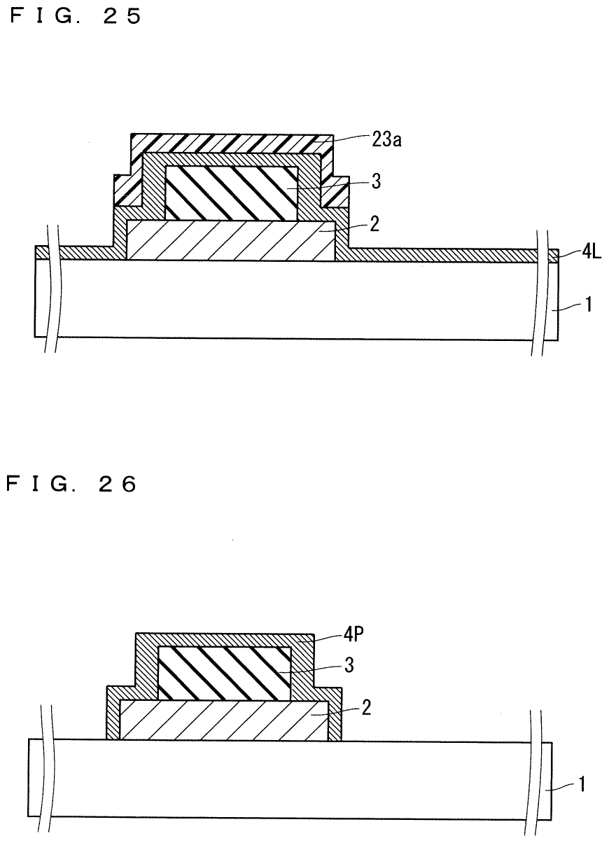

Next, as shown in FIG. 25, the photoresist 23 is patterned by an exposure process using the halftone mask 60B. As a result, the photoresist 23 is patterned such that the stepped portion 23a is formed only in a region covering the gate electrode 2 and the gate insulating film 3.

Then, as shown in FIG. 26, a patterned oxide semiconductor formation layer 4P is obtained by performing an etching process on the oxide semiconductor formation layer 4L with the patterned photoresist 23 as an etching mask. Thereafter, the stepped portion 23a is removed.

The processes shown in FIGS. 25 and 26 correspond to the processes shown in FIG. 17, and the process shown in FIG. 26 shows a state in which the stepped portion 23a is further removed from the process shown in FIG. 17.

Then, as shown in FIG. 27, plasma treatment, which is the reduction treatment, is performed on the oxide semiconductor formation layer 4P whose surface is exposed, to form the light shielding film 50C. As a result, the light shielding film 50C is formed so as to be electrically connected to the gate electrode 2 and to cover the gate electrode 2 and the gate insulating film 3. The light shielding film 50C subjected to the reduction treatment becomes 1×10⁻³ Ω·cm or less, and the property changes from semiconductor to conductor, similarly to the light shielding film 50A and the light shielding film 50B. Note that the process shown in FIG. 27 corresponds to the processes shown in FIGS. 18 and 19.

Thereafter, through the processes shown in FIGS. 20 to 23, the gate terminal portion 30 shown in FIG. 3 is completed by forming the drain electrode 7 and the pixel electrode 9 after providing a gate terminal contact hole 12 in the protective insulating film 6.

Thus, since the photoresist 23 having the first and second regions with different film thicknesses is formed by the photoengraving process using the halftone mask 60B, the common electrode 5 and the light shielding film 50C can be formed by using one photoresist 23. As a result, the number of photoengraving processes required to form the common electrode 5 and the light shielding film 50C can be reduced to one, which simplifies the manufacturing process.

Further, similarly to the light shielding film 50A and the light shielding film 50B, since the light shielding film 50C, which is the second light shielding film, has, as a constituent material, a same oxide semiconductor as the constituent material of the semiconductor channel layer 4, the light shielding film 50C can be formed together with the formation of the semiconductor channel layer 4, so that productivity of the thin-film transistor substrate can be improved by reducing the number of masks for patterning.

In addition, by setting a specific resistance of each light shielding film 50C, which is the second light shielding film, to be low by plasma treatment as the reduction treatment, it is possible to improve resistance loss when current flows through the light shielding film 50C.

The gate terminal portion 30 shown in FIG. 3 is a region in which the gate electrode 2 is formed extending outside the pixel configuration region including the TFT portion 71 and the pixel portion 72.

As shown in the same figure, the light shielding film 50C, which is the second light shielding film having conductivity, is provided above the gate electrode 2, and the light shielding film 50C is electrically connected to the gate electrode 2 and is formed to overlap with the gate electrode 2 in a plan view as shown in FIGS. 1 and 3.

As described above, in the TFT substrate 100 of the first embodiment, the gate terminal contact hole 12 may simply be provided so as to reach the light shielding film 50C, by providing the light shielding film 50C, which is the second light shielding film.

Therefore, in a case where the gate terminal contact hole 12 is formed simultaneously with the drain contact hole 10 and the source contact hole 11, the drain contact hole 10 and the source contact hole 11 are not adversely affected by excessive etching or the like by the formation of the gate terminal contact hole 12. As a result, control of a finished size and a cross-sectional structure of the drain contact hole 10 and the source contact hole 11 becomes easier, and the coverage of the drain electrode 7 and the source electrode 8 can be improved.

This point will be described in detail below. In the first embodiment, as shown in FIG. 3, on the gate electrode 2 in the gate terminal portion 30, the light shielding film 50C electrically connected to the gate electrode 2 is formed to be electrically connected to the gate electrode 2 on the gate electrode 2.

Therefore, in the gate terminal portion 30, the gate terminal contact hole 12 can be formed by penetrating the protective insulating film 6 and guiding to the light shielding film 50C having conductivity. Therefore, the gate terminal contact hole 12 can be processed under the same etching conditions as those of the drain contact hole 10 and the source contact hole 11. This is because, as shown in FIG. 21, the drain contact hole 10 and the source contact hole 11 can also be formed by penetrating the protective insulating film 6.

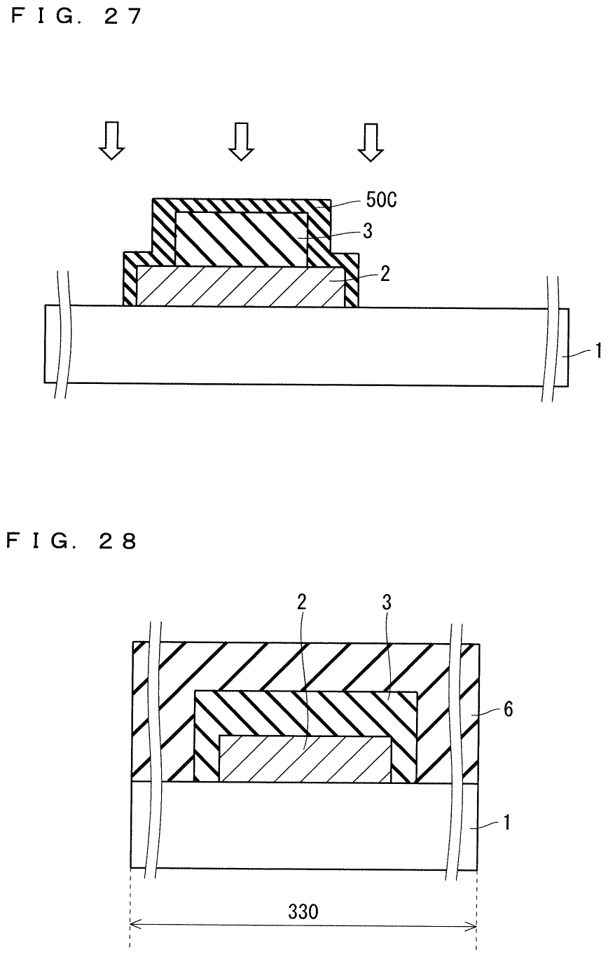

FIG. 28 is a cross-sectional view showing a configuration of a gate terminal portion 330 in which the light shielding film 50C is not formed. As shown in the same figure, a gate insulating film 3 is formed on a gate electrode 2, and a protective insulating film 6 is formed to cover the gate insulating film 3.

In the gate terminal portion 330 shown in FIG. 28, since the gate insulating film 3 is further provided between the gate electrode 2 and the protective insulating film 6, processing cannot be performed under the same etching conditions as those of the drain contact hole 10 and the source contact hole 11 in which the gate insulating film 3 is not provided between the protective insulating film 6 and the semiconductor channel layer 4.

Therefore, in a case of patterning by one photoengraving process, it is necessary to perform excessive etching more than an optimum etching time, which consequently increases a finished opening size of the drain contact hole 10 and the source contact hole 11, causing a problem such as a processed shape that deteriorates the coverage of the drain electrode 7 and the source electrode 8, that is, a cross-sectional shape that deteriorates the coverage. However, in the gate terminal portion 30 shown in FIG. 3, the above problem does not occur.

Further, since the light shielding film 50C having a relatively low specific resistance of 1×10⁻³ Ω·cm or less can be formed, a wiring resistance associated with the gate electrode 2 can be lowered to improve the resistance loss.

Further, since the gate electrode 2 of the gate terminal portion 30 is protected by the light shielding film 50C, a metal that is easily etched or oxidized, such as Ti, Mo, Al, Cu, and alloys thereof can be used as the electrode material, while the gate electrode 2 is not directly exposed to dry etching using a fluorine-containing gas such as CHF₃, CF₄, or SF₆ and an oxygen (O₂) gas. Accordingly, as shown in FIG. 3, in the gate terminal portion 30, the gate electrode 2 is electrically connected to the metal electrode of the drain electrode 7 and the pixel electrode 9 via the light shielding film 50C. Note that the drain electrode 7 and the pixel electrode 9 formed in the gate terminal portion 30 are provided for protecting the light shielding film 50C, and do not have an original function.

Further, in the first embodiment, while a structure is shown in which the light shielding film 50C is formed in the gate terminal portion 30, the source terminal portion 40 can be similarly formed in a structure having the light shielding film 50C shown in FIG. 3, and an effect similar to that in the case of forming the light shielding film 50C in the gate terminal portion 30 is achieved.

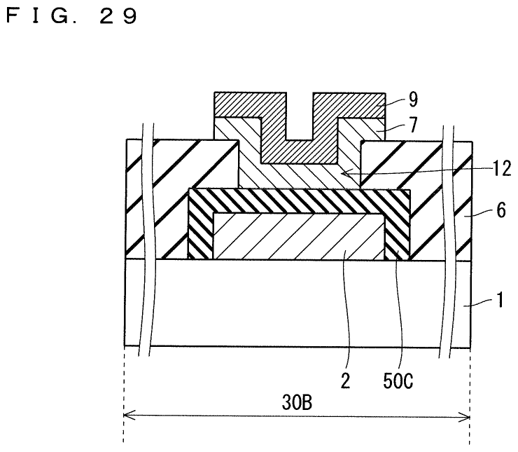

FIG. 29 is a cross-sectional view showing a configuration of a gate terminal portion 30B, which is a modification of the gate terminal portion 30. As shown in the same figure, a light shielding film 50C is formed so as to directly cover a gate electrode 2 without a gate insulating film 3 provided on the gate electrode 2. Then, a drain electrode 7 and a pixel electrode 9 are deposited on the light shielding film 50C through a gate terminal contact hole 12.

In the gate insulating film 3, for example, in the process shown in FIG. 12, as a result of being completely removed in performing the processes shown in FIGS. 14 and 15, by setting the entire surface on the gate insulating film 3 as the stepped portion 22a of the photoresist 22, it is possible to realize a structure in which the gate insulating film 3 on the gate electrode 2 in the gate terminal portion 30B is not formed at all as shown in FIG. 29.

Thus, the light shielding film 50C can be connected to an end of the gate electrode 2 as shown in FIG. 3, or can be connected to the gate electrode 2 in a structure in which the entire surface of the gate insulating film 3 is etched as shown in FIG. 29. That is, it is possible to realize various combinations of electrical connection between the gate electrode 2 and the light shielding film 50C, by changing the amount of etching removal of the gate insulating film 3.

Furthermore, the thin-film transistor substrate in which the plurality of pixel configuration regions are arranged in a matrix form of the first embodiment has the following configuration.

In the first embodiment, since the second light shielding film (50C) has, as a constituent material, a same oxide semiconductor as the constituent material of the semiconductor channel layer, a light shielding film can be formed together with the formation of the semiconductor channel layer, so that productivity of the thin-film transistor substrate can be improved by reducing the number of masks for patterning.

Further, since the second light shielding film having a relatively low specific resistance can be formed, a wiring resistance associated with the gate electrode can be lowered to improve the resistance loss.

The second light shielding film has an oxide semiconductor as a constituent material, and its specific resistance is set to 1×10⁻³ Ω·cm or less, which is lower than a specific resistance of the semiconductor channel layer.

By setting a specific resistance of the second light shielding film to be low, it is possible to improve the resistance loss when current flows through the second light shielding film.

After completion of the TFT substrate 100, an alignment film and a spacer (not shown) are formed on the surface of the TFT substrate 100. The alignment film is a film for aligning liquid crystals, and is made of polyimide and the like.

Here, a color filter is actually provided on a counter substrate disposed opposite to the TFT substrate 100. The TFT substrate 100 and the counter substrate are bonded while maintaining a fixed gap by the spacer above, and the liquid crystal is injected and sealed in the gap. That is, the liquid crystal layer is sandwiched between the TFT substrate 100 and the counter substrate. Two polarizing plates and a backlight are disposed on outer surfaces of the TFT substrate 100 and the counter substrate bonded in this manner, so that an FFS liquid crystal display apparatus can be obtained. In the present embodiment, the backlight is to be disposed on a back-surface side of the transparent insulating substrate 1.

The liquid crystal display apparatus obtained in this manner has characteristics of high resolution, high frame rate, long life, and high reliability.

As described above, in the first embodiment, without increasing the number of photoengraving processes, an etching stopper TFT using an oxide semiconductor film as the semiconductor channel layer 4 of the TFT substrate 100 can be manufactured with high productivity by a relatively simple manufacturing process.

Furthermore, the drain contact hole 10 and the source contact hole 11 can be processed into a desired shape, the coverage of the electrode is excellent, deterioration in yield such as film peeling of the TFT portion 71 or disconnection of the source electrode 8 and the pixel electrode 9 is suppressed.

Further, the light shielding films 50A to 50C subjected to the reduction treatment can provide an effect of reducing intensity of light of a wavelength that adversely affects the TFT characteristics, and also exhibits an effect of improving the long-term reliability.

In the first embodiment described above, the thin-film transistor substrate has a plurality of pixel configuration regions arranged in a matrix form, each of the plurality of pixel configuration regions includes a TFT portion (71) and a pixel portion (72), and each of the plurality of pixel configuration regions includes a gate electrode (2), a gate insulating film (3), a semiconductor channel layer (4), a common electrode (5), a protective insulating film (6), a drain electrode (7), a source electrode (8), and a pixel electrode (9).

The gate electrode (2) is selectively provided on a substrate (1), the gate insulating film (3) is provided on the gate electrode, and the semiconductor channel layer (4) is provided on the gate insulating film.

The common electrode (5) is selectively provided on the substrate, and the protective insulating film (6) covers the substrate including the gate electrode, the gate insulating film, the semiconductor channel layer, and the common electrode. The drain electrode (7) and the source electrode (8) are electrically connected to the semiconductor channel layer through a drain contact hole (10) and a source contact hole (11) provided in the protective insulating film, and are provided independently of each other. The pixel electrode (9) is provided extending from on the drain electrode to the pixel portion.

The TFT portion is configured by the gate electrode, the gate insulating film, the semiconductor channel layer, the source electrode, the drain electrode, and a part of the pixel electrode, and the pixel portion is configured by the common electrode and a main part of the pixel electrode.

Then, it is characterized in that a first light shielding film (50A, 50B, 52, 53) is provided below at least one electrode of the source electrode or the drain electrode, in a region overlapping with the at least one electrode in plan view.

A first aspect of the thin-film transistor substrate according to the present invention exhibits effects of being able to, due to the presence of the first light shielding film, suppress light intensity and a light amount of incident light, such as an LED from a back-surface side of the substrate, reflected by the source electrode or the drain electrode to be incident on the semiconductor channel layer, and being able to shield the incident light itself on the semiconductor channel layer.

Then, it is characterized in that the gate electrode is formed extending to a gate terminal portion (30) disposed outside the pixel configuration region, a second light shielding film (50C) having conductivity is provided above the gate electrode in the gate terminal portion, and the second light shielding film is electrically connected to the gate electrode and overlaps with the gate electrode in plan view.

In a second aspect of the thin-film transistor substrate of the present invention, a second light shielding film having conductivity is provided above the gate electrode, and this second light shielding film is electrically connected to the gate electrode and overlaps with the gate electrode in plan view. Therefore, the gate terminal contact hole provided to achieve electrical connection with the gate electrode may simply be provided to reach the second light shielding film.

Therefore, in the second aspect, in a case where the gate terminal contact hole is formed simultaneously with the drain contact hole and the source contact hole, the drain contact hole and the source contact hole source are not adversely affected by excessive etching or the like due to the formation of the gate terminal contact hole. As a result, in the second aspect, control of a finished size and a cross-sectional structure of the drain contact hole and the source contact hole becomes easier, and the coverage of the source electrode and the drain electrode can be improved.

### Second Embodiment

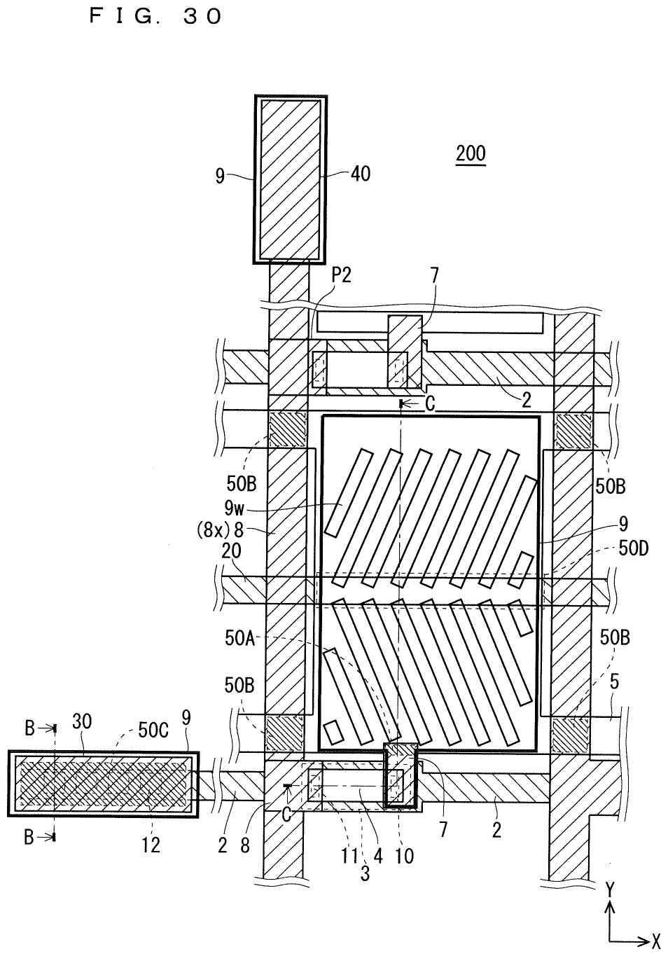

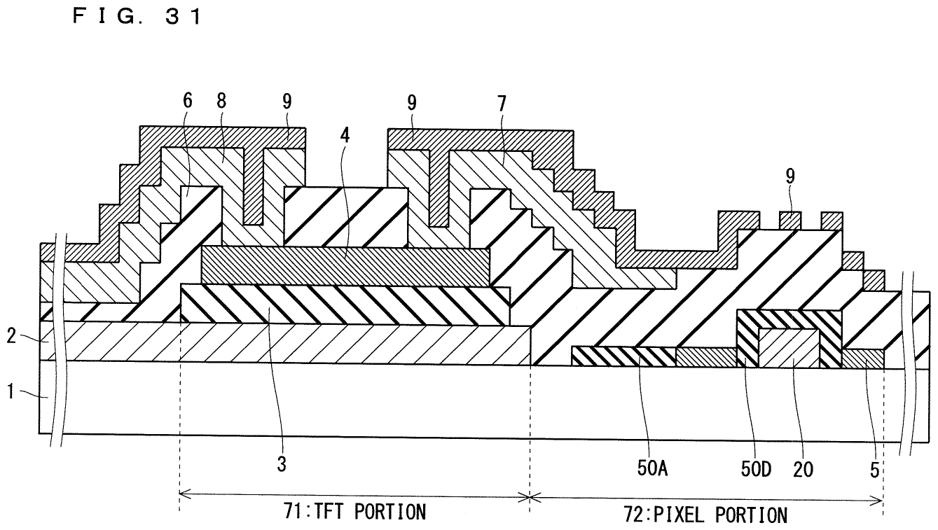

FIG. 30 is a plan view showing a configuration of a TFT substrate 200, which is a thin-film transistor substrate as a second embodiment of the present invention, and FIG. 31 is a cross-sectional view showing a cross-sectional structure taken along line C-C in FIG. 30. Meanwhile, FIG. 30 shows an XY orthogonal coordinate system.

Hereinafter, a configuration and a method for manufacturing the TFT substrate 200 as the second embodiment of the present invention will be described with reference to FIGS. 30 and 31. Note that the same configurations as those of the TFT substrate 100 are denoted by the same reference numerals, and redundant description will be omitted as appropriate.

Since the cross-sectional configuration taken along line B-B in FIG. 30 is the same as that of the TFT substrate 100 shown in FIG. 3, the description will be omitted.

As shown in FIGS. 30 and 31, the TFT substrate 200 is different from the TFT substrate 100 of the first embodiment in that, in addition to a light shielding film 50A formed on a part of a common electrode 5, a common wiring 20 is formed simultaneously with a gate electrode 2, and there is further provided a light shielding film SOD electrically connected to the common wiring 20. The common wiring 20 is formed to extend in the X direction, to be disposed parallel to the plurality of gate electrodes 2 each serving as a scanning signal line, and to be electrically connected to the common electrode 5.

As shown in FIG. 31, the light shielding film SOD is formed directly covering the common wiring 20, and the common electrode 5 is provided continuously from the light shielding film 50D.

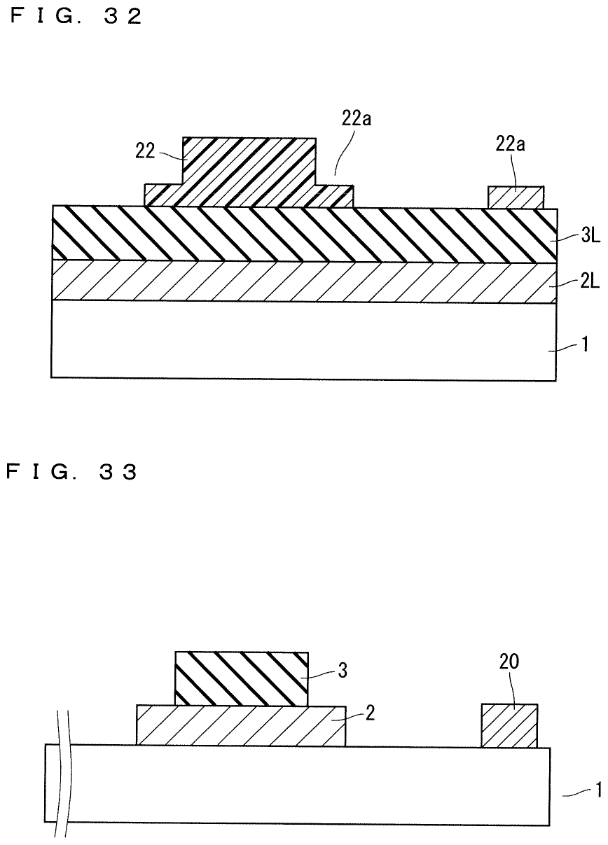

FIGS. 32 to 37 are cross-sectional views showing a forming process of the light shielding film SOD, which is a part of the method for manufacturing the TFT substrate 200 of the second embodiment.

As shown in FIG. 32, after a conductive layer 2L and an insulating layer 3L are laminated on a transparent insulating substrate 1, a photoresist 22 is applied on the insulating layer 3L, and the photoresist 22 is patterned in a structure having a stepped portion 22a. The process shown in FIG. 32 corresponds to the process shown in FIG. 12 of the first embodiment.

Then, the first etching process is performed on the conductive layer 2L and the insulating layer 3L with the patterned photoresist 22 as an etching mask, to obtain the gate electrode 2, the gate insulating film 3, and the common wiring 20. Thereafter, the stepped portion 22a of the photoresist 22 is removed, and then the second etching process is further performed on the gate insulating film 3 with the photoresist 22 as an etching mask.

As a result, as shown in FIG. 33, a gate insulating film reduction structure in which the gate insulating film 3 is not formed on a peripheral region of the gate electrode 2 is obtained. At the same time, all the gate insulating film 3 on the common wiring 20 is removed. The process shown in FIG. 33 corresponds to the processes shown in FIGS. 13 to 15 of the first embodiment.

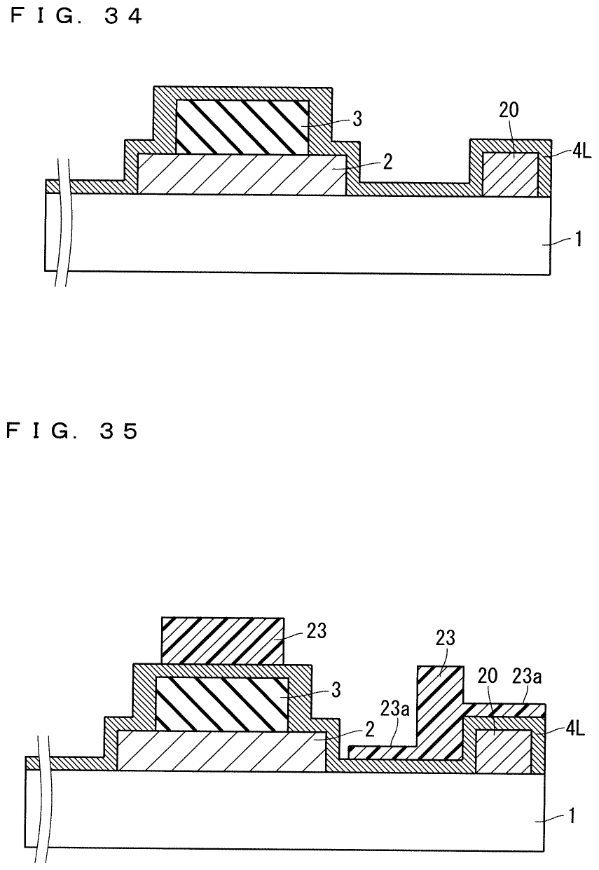

Thereafter, as in FIG. 34, an oxide semiconductor formation layer 4L is formed on the entire surface of the transparent insulating substrate 1 including the gate electrode 2 and the gate insulating film 3. The process shown in FIG. 34 corresponds to the process shown in FIG. 16 of the first embodiment.

Next, as shown in FIG. 35, a patterned photoresist 23 having a stepped portion 23a is formed on the oxide semiconductor formation layer 4L.

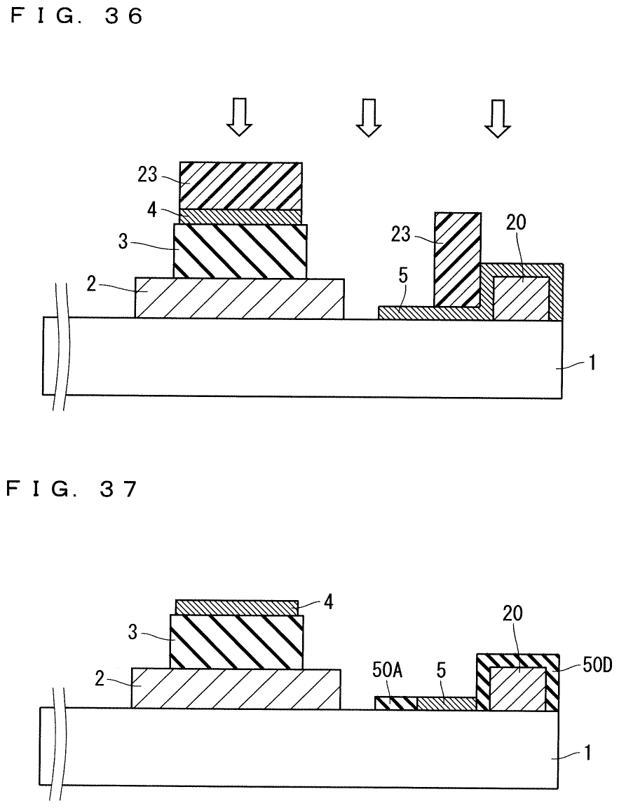

Then, as shown in FIG. 36, by etching the oxide semiconductor formation layer 4L with the patterned photoresist 23 as an etching mask, a semiconductor channel layer 4 is formed on the gate insulating film 3, and at the same time, the common electrode 5 is selectively formed on the transparent insulating substrate 1 and on the common electrode 5.

Further, as shown in FIG. 36, the stepped portion 23a of the photoresist 23 is removed, and reduction treatment by plasma treatment is performed on a part of the common electrode 5 whose surface is exposed, with the photoresist 23 from which the stepped portion 23a is removed as a mask. The processes shown in FIGS. 35 and 36 correspond to the processes shown in FIGS. 17 and 18 of the first embodiment.

As a result, as shown in FIG. 37, the light shielding film 50A is formed continuously adjacent to the common electrode 5, and the light shielding film 50D is simultaneously formed to directly cover the common wiring 20. Thereafter, the photoresist 23 is removed. The process shown in FIG. 37 corresponds to the process shown in FIG. 19 of the first embodiment.

Thus, the TFT substrate 200 of the second embodiment has characteristics of including: the common wiring 20 that is electrically connected to the common electrode 5, overlaps at a central portion of the pixel electrode 9 in plan view in the pixel portion 72, and intersects with the pixel electrode 9; and the light shielding film 50D that is a common-wiring light shielding film provided directly covering the common wiring 20. Since the common wiring 20 is formed of a metal that is a same constituent material as that of the gate electrode 2, the conductivity is higher, and the light transmittance is lower than that of the common electrode 5.

Since the TFT substrate 200 of the second embodiment can reduce a wiring resistance associated with the common electrode 6 by providing the common wiring 20 electrically connected to the common electrode 5, occurrence of response delay and display failure can be suppressed even when an operation related to a pixel is performed in a high-speed state.

Furthermore, in the TFT substrate 200 of the second embodiment, due to the presence of the light shielding film 50D, which is the common-wiring light shielding film, it is possible to suppress light intensity and a light amount of incident light, such as an LED from a back-surface side of the transparent insulating substrate 1, reflected by the source electrode 8 or the drain electrode 7 to be incident on the semiconductor channel layer 4.

In the second embodiment, one common wiring 20 is disposed corresponding to one gate electrode 2, but a plurality of common wirings 20 may be disposed in consideration of an opening ratio of the pixel portion 72 and an optimum value of the wiring resistance.

In the first embodiment, while the TFT substrate 100 is created by the five photoengraving processes using the halftone mask 60B, five photoengraving processes can be performed also in the second embodiment. That is, in the second embodiment, it is possible to manufacture an etching stopper TFT using an oxide semiconductor film as the semiconductor channel layer 4 of the TFT substrate 200 with high productivity, by a relatively simple manufacturing process without greatly increasing the number of photoengraving processes.

Further, the light shielding film 50A and the light shielding film 50D subjected to the reduction treatment can provide an effect of reducing intensity of light of a wavelength that adversely affects the TFT characteristics, and also exhibit an effect of improving the long-term reliability.

### Third Embodiment

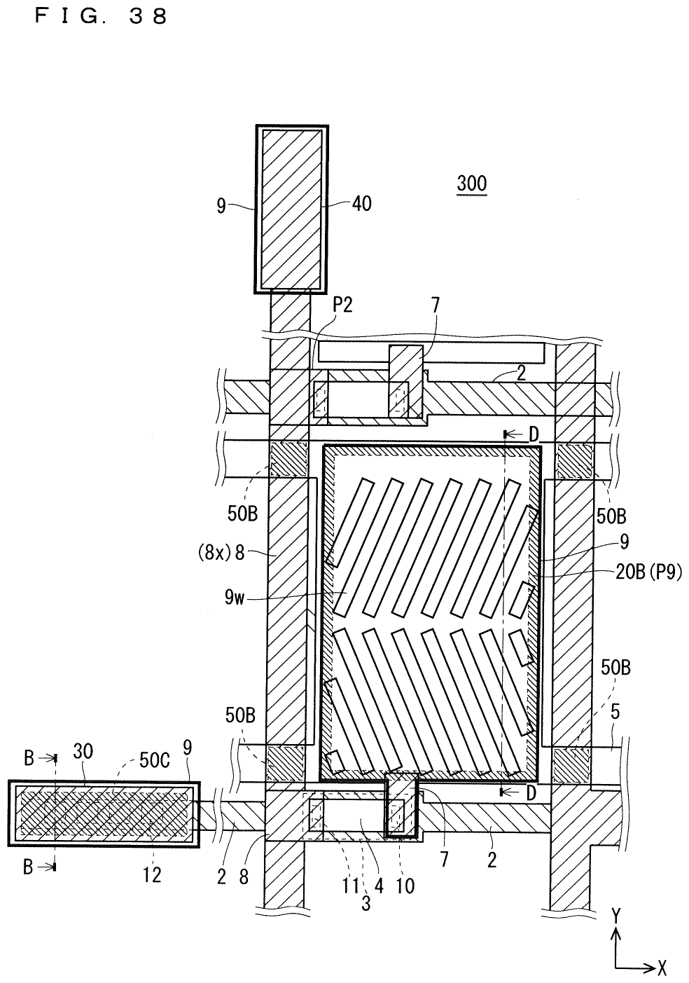

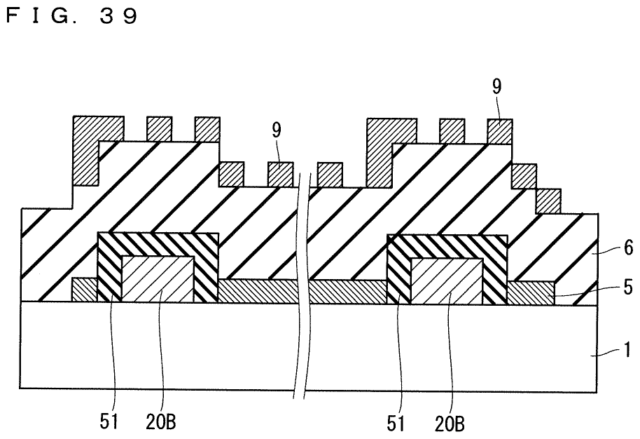

FIG. 38 is a plan view showing a configuration of a TFT substrate 300, which is a thin-film transistor substrate forming a liquid crystal display apparatus as a third embodiment of the present invention, and FIG. 39 is a cross-sectional view showing a cross-sectional structure taken along line D-D in FIG. 38. Meanwhile, FIG. 38 shows an XY orthogonal coordinate system.

Hereinafter, a configuration and a method for manufacturing the TFT substrate 300 of the third embodiment will be described with reference to FIGS. 38 and 39. Note that the same configurations as those of the TFT substrate 100 are denoted by the same reference numerals, and redundant description will be omitted as appropriate.

As shown in FIGS. 38 and 39, there is further provided a common wiring 20B electrically connected to a common electrode 5 and formed so as to overlap with a peripheral region P9 of a pixel electrode 9 in plan view in a pixel portion 72. Then, as shown in FIG. 39, there is provided a light shielding film 51 that is a light shielding film for a pixel peripheral common wiring to directly cover the common wiring 20B. That is, in the TFT substrate 100 of the third embodiment, the light shielding film 51 is provided instead of the light shielding film 50A.

Note that the common wiring 20B and the light shielding film 51 can be manufactured by a manufacturing method similar to that of the common wiring 20 and the light shielding film 50D shown in FIGS. 32 to 37 of the second embodiment.

In the TFT substrate 300 of the third embodiment, by providing the light shielding film 51, which is a light shielding film for a pixel peripheral common wiring, along the peripheral region P9 of the pixel electrode 9 of the pixel portion 72, a formation area of the light shielding film 51 in a region near a semiconductor channel layer 4 can be formed wider than that of the light shielding film 50A of the first embodiment.

As a result, it is possible to further exert suppression of light intensity and a light amount of incident light incident on the semiconductor channel layer 4, such as an LED from a back-surface side of a transparent insulating substrate 1, as compared with the first embodiment.

In the third embodiment, the common wiring 20B and the light shielding film 51 are disposed along the peripheral region P9 of the pixel electrode 9 in the pixel portion 72, but a plurality of these may be disposed in the pixel in consideration of an opening ratio of the pixel portion 72 and an optimum value of the wiring resistance.

### Fourth Embodiment

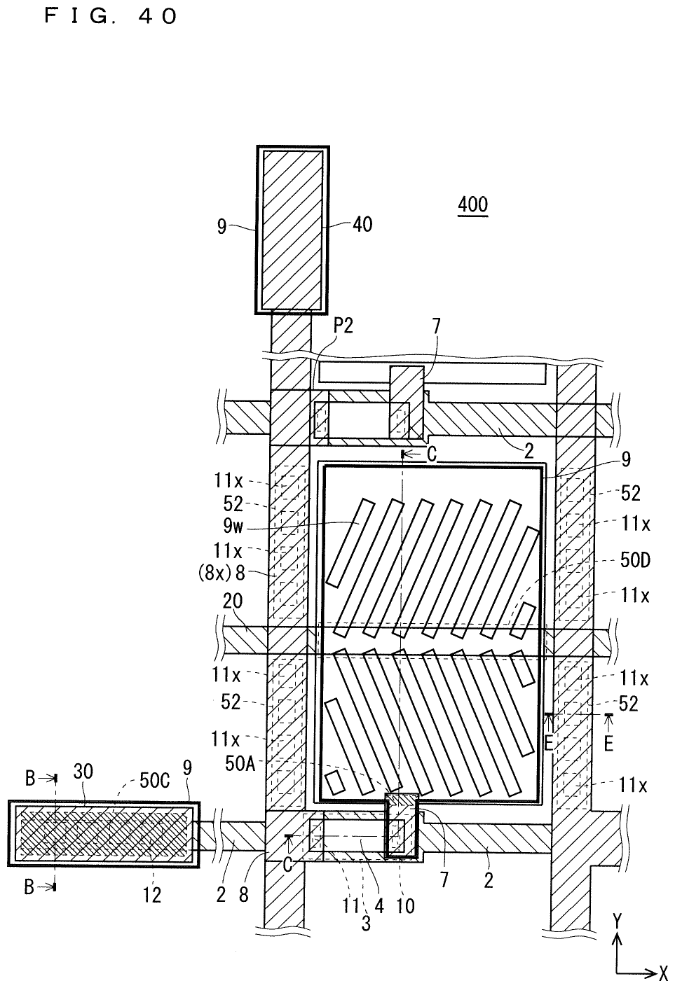

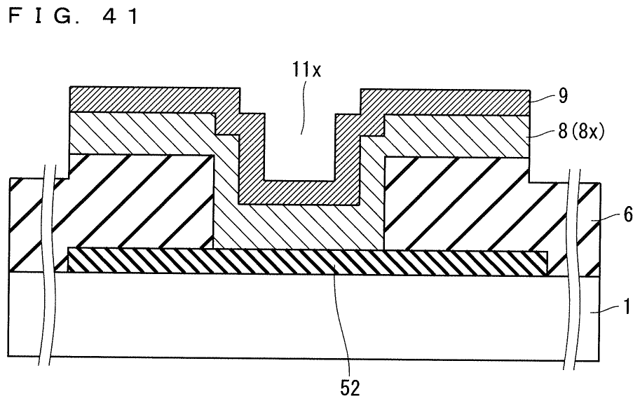

FIG. 40 is a plan view showing a configuration of a TFT substrate 400, which is a thin-film transistor substrate forming a liquid crystal display apparatus as a fourth embodiment of the present invention, and FIG. 41 is a cross-sectional view showing a cross-sectional structure taken along line E-E in FIG. 40. Meanwhile, FIG. 40 shows an XY orthogonal coordinate system.

Hereinafter, a configuration and a method for manufacturing the TFT substrate 400 as the fourth embodiment will be described with reference to FIGS. 40 and 41. Note that the same configurations as those of the TFT substrate 100 of the first embodiment and the TFT substrate 200 of the second embodiment are denoted by the same reference numerals, and redundant description will be appropriately omitted.

As shown in FIGS. 40 and 41, a source electrode 8 has a source electrode extension region 8x provided along the Y direction toward a source terminal portion 40 disposed outside a pixel configuration region constituted of a TFT portion 71 and a pixel portion 72.

Then, on a transparent insulating substrate 1 below the source electrode 8, in a region overlapping with the source electrode extension region 8x in plan view, there is formed a light shielding film 52, which is a source-dedicated light shielding film directly connected to the source electrode extension region 8x. This light shielding film 52 has conductivity.

Thus, in the TFT substrate 400 of the fourth embodiment, below the source electrode extension region 8x of the source electrode 8, the light shielding film 52 is formed as a first light shielding film provided in a region overlapping with the source electrode extension region 8x of the source electrode 8 in plan view.

As shown in FIG. 40, in each source electrode extension region 8x of one source electrode 8, the light shielding films 52 are provided at two places in one-pixel unit, and each light shielding film 52 is electrically connected to the source electrode extension region 8x of the source electrode 8 through source contact holes 11x at four places.

Meanwhile, the light shielding film 52 can be manufactured by a manufacturing method similar to that of the light shielding film 50A of the first embodiment shown in FIGS. 16 to 19. A protective insulating film 6, the source electrode 8, and a pixel electrode 9 can be manufactured by a manufacturing method similar to that of the protective insulating film 6, the drain electrode 7, and the pixel electrode 9 of the first embodiment shown in FIGS. 20 and 23. At this time, the source contact hole 11x can be manufactured simultaneously with a source contact hole 11.

As described above, in the fourth embodiment, by electrically connecting the light shielding film 52, which is a source-dedicated light shielding film, to the source electrode extension region 8x of the source electrode 8, a wiring resistance associated with the source electrode 8 can be lowered to reduce a signal delay due to a parasitic capacitance of the source electrode 8. Meanwhile, as the parasitic capacitance of the source electrode 8, a parasitic capacitance between with a formation region of a light shielding film 50B intersecting with a common electrode 5 can be considered.

Furthermore, in the fourth embodiment, due to the presence of the light shielding film 52, which is a source-dedicated light shielding film, it is possible to suppress light intensity and a light amount of incident light, such as an LED from a back-surface side of the transparent insulating substrate 1, reflected by the source electrode extension region 8x of the source electrode 8 to be incident on the semiconductor channel layer 4.

### Modification

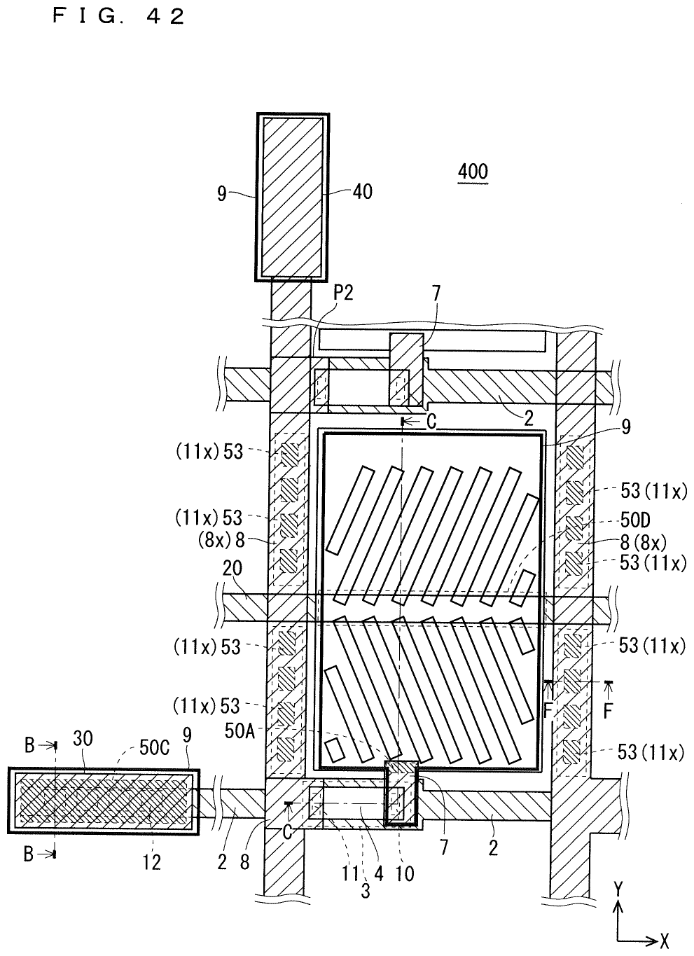

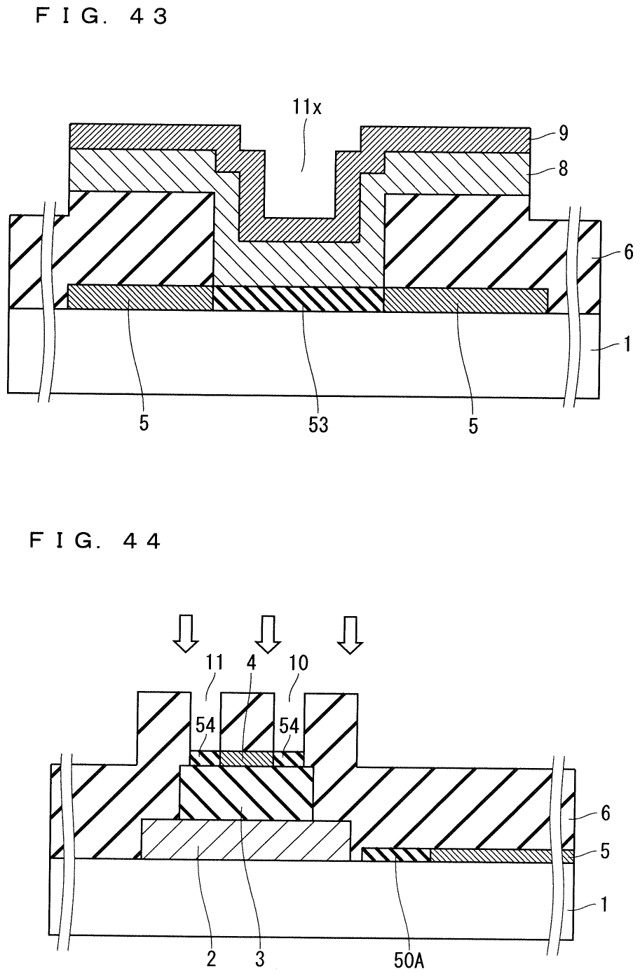

FIG. 42 is a plan view showing a configuration of a TFT substrate 400B, which is a thin-film transistor substrate forming a modification of the liquid crystal display apparatus as the fourth embodiment of the present invention, and FIG. 43 is a cross-sectional view showing a cross-sectional structure taken along line F-F in FIG. 42. Meanwhile, FIG. 42 shows an XY orthogonal coordinate system.

Hereinafter, a structure and a method for manufacturing the TFT substrate 400B that is the modification of the fourth embodiment will be described with reference to FIGS. 42 and 43. Note that the same configurations as those of the TFT substrate 100 of the first embodiment and the TFT substrate 200 of the second embodiment are denoted by the same reference numerals, and redundant description will be appropriately omitted.

As shown in FIGS. 42 and 43, on a transparent insulating substrate 1 below a source electrode 8, in a region overlapping with a source electrode extension region 8x in plan view, there is formed a light shielding film 53, which is a source-dedicated light shielding film directly connected to the source electrode extension region 8x. This light shielding film 53 has conductivity.

Thus, in the TFT substrate 400B of the modification of the fourth embodiment, below the source electrode extension region 8x of the source electrode 8, the light shielding film 53 is formed as a first light shielding film provided in a region overlapping with the source electrode extension region 8x of the source electrode 8 in plan view.

The light shielding film 53 is selectively formed only in a region immediately below a source contact hole 11x in a common electrode 5. Note that the common electrode 5 shown in FIG. 43 is merely provided for the formation of the light shielding film 53, and does not have an original function.

As shown in FIG. 42, in each source electrode extension region 8x of one source electrode 8, the light shielding films 53 are provided at eight places in one-pixel unit, and each light shielding film 53 is electrically connected to the source electrode extension region 8x of the source electrode 8 through source contact holes 11x at eight places corresponding one-to-one.

Meanwhile, the light shielding film 53 can be manufactured by a manufacturing method similar to that of the light shielding film 50A of the first embodiment shown in FIGS. 16 to 19. A protective insulating film 6, the source electrode 8, and a pixel electrode 9 can be manufactured by a manufacturing method similar to that of the protective insulating film 6, the drain electrode 7, and the pixel electrode 9 of the first embodiment shown in FIGS. 20 and 23. At this time, the source contact hole 11x can be manufactured simultaneously with a source contact hole 11.

Further, the common electrode 5 may be formed in the processes shown in FIGS. 16 to 19, and after the formation of the source contact hole 11x, the light shielding film 53 may be formed by performing plasma treatment, which is reduction treatment, on the common electrode 5 below the source contact hole 11x.

Thus, in the modification of the fourth embodiment, it is possible to reduce a signal delay due to a parasitic capacitance of the source electrode 8, by electrically connecting the light shielding film 53, which is a source-dedicated light shielding film, to the source electrode extension region 8x of the source electrode 8, to lower a wiring resistance associated with the source electrode 8.

Furthermore, in the modification of the fourth embodiment, due to the presence of the light shielding film 53, which is a source-dedicated light shielding film, it is possible to suppress light intensity and a light amount of incident light, such as an LED from a back-surface side of the transparent insulating substrate 1, reflected by the source electrode extension region 8x of the source electrode 8 to be incident on a semiconductor channel layer 4.

The fourth embodiment has shown a structure in which the light shielding film 52 or the light shielding film 53 is electrically connected to the source electrode 8 for the purpose of reducing the signal delay of the source electrode 8 due to capacitance formation.

It is possible to obtain an effect that the light shielding film 52 and the light shielding film 53 subjected to the reduction treatment reduce light intensity of a wavelength that adversely affects the TFT characteristics, and to also achieve the effect of improving the long-term reliability, similarly to the first to third embodiments.

<Others>

In the first to fourth embodiments described above, it is important for improving the reliability of the thin-film transistor to form the light shielding films 50A to 50D and the light shielding films 51 to 53 subjected to the reduction treatment on a part of the common electrode 5, increase a light absorption rate at a wavelength of 500 nm or less in particular, and weaken light intensity incident on the semiconductor channel layer 4.

Therefore, it is possible to obtain an effect that the light shielding films 50A to 50D and the light shielding films 51 to 53 subjected to the reduction treatment reduce light intensity of a wavelength that adversely affects the TFT characteristics.

FIG. 44 is a cross-sectional view showing a modified manufacturing method of the present embodiment. As shown in the same figure, the drain contact hole 10 and the source contact hole 11 are patterned by the third photoengraving process, and the protective insulating film 6 made of a silicon oxide film and a silicon nitride film is etched by a dry etching method using a fluorine-containing gas such as CHF₃, CF₄, or SF₆ and an oxygen (O₂) gas.

Thereafter, plasma treatment including hydrogen (H₂), helium (He), and nitrogen (N₂) may be continuously performed to form a light shielding film 54 on a part of the semiconductor channel layer 4.

At this time, as shown in the first to fourth embodiments, by combining with the process of forming the light shielding film 50B on a portion where the source electrode 8 and the common electrode 5 are in tolerance, the light shielding film 50D can be formed on a part of the common wiring 20 as described in the second embodiment, to reduce light intensity of the LED reflected from the source electrode 8.

While the present invention has been described in detail, the foregoing description is in all aspects illustrative, and the present invention is not limited thereto. It is understood that innumerable modifications not illustrated can be envisaged without departing from the scope of the present invention.

That is, the present invention can freely combine each embodiment within the scope of the invention, and can deform or omit each embodiment as appropriate.

Furthermore, the present invention is not limited to the above embodiments, and can be variously modified in the implementation phase without departing from the scope of the invention. In addition, the above embodiments include the invention of various phases, and various inventions can be extracted by appropriate combinations of a plurality of disclosed configuration requirements.

For example, even if some configuration requirement is removed from all the configuration requirements shown in each of the first to fourth embodiments, in a case where it is possible to solve the problem described in the section of Problem to be Solved by the Invention, and to obtain the effect described in the section of Effects of the Invention, a configuration from which this configuration requirement has been removed can be extracted as the invention. Furthermore, the configuration requirements according to the above first to fourth embodiments and the modification may be combined as appropriate.

### EXPLANATION OF REFERENCE SIGNS

1: transparent insulating substrate
2: gate electrode
3: gate insulating film
4: semiconductor channel layer
4L: oxide semiconductor formation layer
5: common electrode
6: protective insulating film
7: drain electrode
8: source electrode
9: pixel electrode
10: drain contact hole
11: source contact hole
12: gate terminal contact hole
20, 20B: common wiring
50A to 50D, 51 to 53: light shielding film
100, 200, 300, 400, 400B: TFT substrate

1. A thin-film transistor substrate in which a plurality of pixel configuration regions are arranged in a matrix form, wherein
each of the plurality of pixel configuration regions includes a TFT portion and a pixel portion,
each of the plurality of pixel configuration regions comprises:
a gate electrode selectively provided on a substrate;
a gate insulating film provided on the gate electrode;
a semiconductor channel layer provided on the gate insulating film;
a common electrode selectively provided on the substrate, wherein the common electrode is provided directly on the substrate independently of the gate electrode and the gate insulating film,
each of the plurality of pixel configuration regions further comprises:
a protective insulating film covering over the substrate including the gate electrode, the gate insulating film, the semiconductor channel layer, and the common electrode;
a drain electrode and a source electrode that are electrically connected to the semiconductor channel layer through a drain contact hole and a source contact hole provided in the protective insulating film, and are provided independently of each other; and
a pixel electrode provided extending from on the drain electrode to the pixel portion,
the TFT portion is configured by the gate electrode, the gate insulating film, the semiconductor channel layer, the source electrode, the drain electrode, and a part of the pixel electrode, and the pixel portion is configured by the common electrode and a main part of the pixel electrode, and
a first light shielding film is provided below at least one electrode of the source electrode or drain electrode, in a region overlapping with the at least one electrode in plan view, and provided directly on the substrate to be adjacent to the common electrode.

2. (canceled)

3. The thin-film transistor substrate according to claim 1, wherein
the first light shielding film
has, as a constituent material, a same oxide semiconductor as a constituent material of the semiconductor channel layer, and is provided on the substrate in a state of being electrically separated from the gate electrode.

4. The thin-film transistor substrate according to claim 3, wherein
the first light shielding film
includes a drain light shielding film that is formed continuously adjacent to the common electrode and formed in a region overlapping with the drain electrode in plan view.

5. The thin-film transistor substrate according to claim 3, wherein
the source electrode further includes a source electrode extension region formed toward a source terminal portion disposed outside the pixel configuration region, and
the first light shielding film
includes a source light shielding film formed continuously adjacent to the common electrode, in a region where the common electrode and the source electrode extension region overlap in plan view.

6. The thin-film transistor substrate according to claim 3, further comprising:
a common wiring electrically connected to the common electrode and overlapping at a central portion of the pixel electrode in plan view in the pixel portion; and
a common-wiring light shielding film provided covering the common wiring.

7. The thin-film transistor substrate according to claim 3, further comprising:
a common wiring electrically connected to the common electrode and formed in a region overlapping with a peripheral region of the pixel electrode in plan view in the pixel portion; and
a light shielding film for a pixel peripheral common wiring provided covering the common wiring.

8. The thin-film transistor substrate according to claim 3, wherein
the source electrode further includes a source electrode extension region provided toward a source terminal portion disposed outside the pixel configuration region, and
the first light shielding film
includes, in a region overlapping with the source electrode extension region in plan view, a source-dedicated light shielding film directly connected to the source electrode extension region and having conductivity.

9. (canceled)

10. The thin-film transistor substrate according to claim 1, wherein
a formation area of the gate insulating film is set smaller than a formation area of the gate electrode in plan view, and a gate insulating film reduction structure is presented in which the gate insulating film is not formed on a peripheral region of the gate electrode.

11. The thin-film transistor substrate according to claim 1, wherein
the first light shielding film
has an oxide semiconductor as a constituent material, and a specific resistance is set to 1×10⁻³ Ω·cm or less that is lower than a specific resistance of the semiconductor channel layer.

12. (canceled)

13. A method for manufacturing the thin-film transistor substrate according to claim 1, comprising the steps of:
(a) selectively forming a gate electrode on a substrate and forming a gate insulating film on the gate electrode;
(b) forming a semiconductor channel layer on the gate electrode, and selectively forming a common electrode on the substrate;
(c) forming a protective insulating film on an entire surface of the substrate including the gate electrode, the gate insulating film, the semiconductor channel layer, and the common electrode; and
(d) selectively penetrating the protective insulating film to form a drain contact hole and a source contact hole, and mutually independently forming the source electrode and the drain electrode to be electrically connected to the semiconductor channel layer, through the drain contact hole and the source contact hole, wherein
the step (b) comprises the steps of:
(b-1) forming an oxide semiconductor formation layer on an entire surface of the substrate including the gate insulating film and the gate electrode;
(b-2) forming, by a photoengraving process using a multi-tone mask, a resist patterned to have first and second regions having mutually different film thicknesses on the oxide semiconductor formation layer, wherein the first region is formed to have a thinner film thickness than that of the second region;
(b-3) patterning the oxide semiconductor formation layer with the resist having the first and second regions as a mask;
(b-4) patterning to allow the first region to be removed from the resist and only the second region to remain; and
(b-5) applying, with the resist having only the second region after the step (b-4) as a mask, reduction treatment on the oxide semiconductor formation layer whose surface is exposed, and forming a first light shielding film, wherein a region corresponding to the second region of the oxide semiconductor formation layer is to be the semiconductor channel layer in the TFT portion, and to be the common electrode in the pixel portion.

14. The method for manufacturing the thin-film transistor substrate according to claim 13, wherein
the reduction treatment performed in the step (b-5) includes plasma treatment using a hydrogen-containing gas.

15. The method for manufacturing the thin-film transistor substrate according to claim 13, wherein
the step (a) comprises the steps of:
(a-1) performing a first etching process on at least one of the gate insulating film or the gate electrode with a gate-related resist as an etching mask; and
(a-2) performing a second etching process on at least one of the gate insulating film or the gate electrode with the gate-related resist as an etching mask, wherein
after performing the step (a), a formation area of the gate insulating film is set smaller than a formation area of the gate electrode in plan view, and a gate insulating film reduction structure is presented in which the gate insulating film is not formed on a peripheral region of the gate electrode.
